(19) United States
(12) Patent Application Publication
(10) Pub. No.: US 2026/0297746 A1
(43) Pub. Date: Oct. 1, 2026

(54) METHOD OF MANUFACTURING THIN FILM BY USING ATOMIC LAYER DEPOSITION METHOD AND METHOD OF MANUFACTURING SEMICONDUCTOR DEVICE USING THE SAME

(71) Applicant: SAMSUNG ELECTRONICS CO., LTD., Suwon-si (KR)

(72) Inventors: Suhwan HWANG, Suwon-si (KR); Younsang KIM, Seoul-si (KR); Chan LEE, Seoul-si (KR)

(73) Assignees: SAMSUNG ELECTRONICS CO., LTD., Suwon-si (KR); Seoul National University R&DB Foundation, Seoul (KR)

(21) Appl. No.: 19/576,409

(22) Filed: Mar. 24, 2026

(30) Foreign Application Priority Data
Apr. 1, 2025 (KR) 10-2025-0042366
Oct. 29, 2025 (KR) 10-2025-0159266

(51) Int. Cl. C23C 16/455; C23C 16/44; C23C 16/505; H10D 30/01; H10P 14/20

(52) U.S. Cl. CPC C23C 16/4554; C23C 16/4408; C23C 16/45542; C23C 16/45553; C23C 16/505; H10D 30/031; H10P 14/3434

(57) ABSTRACT

A method of manufacturing a thin film by using an atomic layer deposition method including at least one cycle, and the at least one cycle includes forming a first adsorption layer onto a substrate for a first supply time, supplying a first purge gas onto the first adsorption layer for a first purge time, forming a second adsorption layer by supplying an inert gas in a plasma state onto the first adsorption layer for a second supply time, supplying a second purge gas onto the second adsorption layer for a second purge time, supplying a reactant gas in a plasma state onto the second adsorption layer for a third supply time to form a thin film, and supplying a third purge gas onto the thin film for a third purge time, in which the second supply time is longer than the first supply time.

### CROSS-REFERENCE TO RELATED APPLICATION

This application is based on and claims priority under 35 USC § 119 to Korean Patent Application No. 10-2025-0042366, filed on Apr. 1, 2025 and Korean Patent Application No. 10-2025-0159266, filed on Oct. 29, 2025, in the Korean Intellectual Property Office, the disclosures of which are incorporated by reference herein in their entireties.

### BACKGROUND

Atomic layer deposition (ALD) is a thin-film process that exploits sequential, self-limiting surface reactions to deliver atomic-level thickness control, excellent step coverage, and compositional uniformity. These characteristics make ALD well suited for depositing thin films on complex three-dimensional features such as high-aspect-ratio trenches, vias, and nanopores. However, as precursor molecular size increases, bulky ligands sterically screen active surface sites, suppressing chemisorption and reducing growth per cycle (GPC), while the longer dose times required to compensate erode overall process throughput. In low-temperature integration schemes (e.g., back-end-of-line processing, flexible substrates), limited thermal energy further impedes ligand elimination and film densification, exacerbating the reactivity losses imposed by steric screening of the precursor. At the device level, such process-induced imperfections manifest as threshold-voltage shifts, hysteresis, leakage current, and degraded bias-stress stability. There is therefore a clear need for approaches that mitigate steric screening and improve surface reactivity while maintaining conformality and film purity under manufacturing-relevant throughput constraints.

### SUMMARY

The disclosure provides a method of manufacturing a thin film by using an atomic layer deposition (ALD) method with improved growth per cycle (GPC).

The disclosure also provides a method of manufacturing a semiconductor device by using an ALD method with an improved GPC.

However, the problems to be solved by the disclosure are not limited to the problems mentioned above, and other problems may be clearly understood by those skilled in the art from the description below.

According to an aspect of the disclosure, there is provided a method of manufacturing a thin film by using an atomic layer deposition method including at least one cycle, wherein the at least one cycle includes forming a first adsorption layer by supplying a metal precursor onto a substrate for a first supply time, supplying a first purge gas onto the first adsorption layer for a first purge time, forming a second adsorption layer by supplying an inert gas in a plasma state onto the first adsorption layer for a second supply time, supplying a second purge gas onto the second adsorption layer for a second purge time, supplying a reactant gas in a plasma state onto the second adsorption layer for a third supply time to allow the second adsorption layer to react with the reactant gas to form a thin film, and supplying a third purge gas onto the thin film for a third purge time, wherein the second supply time is longer than the first supply time.

According to another aspect of the disclosure, there is provided a method of manufacturing a semiconductor device including forming a plurality of bit lines on a substrate, forming a mold layer including a plurality of mold openings exposing upper surfaces of the plurality of bit lines on the plurality of bit lines, forming a channel layer covering sidewalls and bottoms of the plurality of mold openings respectively within the plurality of mold openings of the mold layer, and forming a word line on the channel layer, wherein the forming the channel layer includes forming the channel layer using an atomic layer deposition method including at least one cycle, wherein the at least one cycle includes supplying a metal precursor including one selected from indium (In), gallium (Ga), zinc (Zn), hafnium (Hf), titanium (Ti), aluminum (Al), or zirconium (Zr), onto a substrate to form a first adsorption layer including the metal precursor physically adsorbed onto the substrate, supplying a first purge gas onto the first adsorption layer, forming a second adsorption layer by supplying an inert gas in a plasma state onto the first adsorption layer, supplying a second purge gas onto the second adsorption layer, supplying a reactant gas, which is an oxidizing agent, in a plasma state onto the second adsorption layer to allow the second adsorption layer to react with the reactant gas to form a metal oxide thin film, and supplying a third purge gas onto the metal oxide thin film.

According to another aspect of the disclosure, there is provided a method of manufacturing a thin film by using an atomic layer deposition method including at least one cycle, wherein the at least one cycle includes supplying a metal precursor onto a substrate for a first supply time to form a first adsorption layer including the metal precursor physically adsorbed onto the substrate, supplying a first purge gas onto the first adsorption layer for a first purge time, forming a second adsorption layer by supplying an inert gas in a plasma state onto the first adsorption layer for a second supply time, supplying a second purge gas onto the second adsorption layer for a second purge time, supplying a reactant gas in a plasma state onto the second adsorption layer for a third supply time to allow the second adsorption layer to react with the reactant gas to form a thin film, and supplying a third purge gas onto the thin film for a third purge time, wherein the second supply time is longer than the first supply time, the first purge time is longer than the first supply time, the second purge time is longer than the second supply time, and the inert gas is helium or a mixed gas of helium and argon.

### BRIEF DESCRIPTION OF THE DRAWINGS

Embodiments are more clearly understood from the following detailed description taken in conjunction with the accompanying drawings in which:

FIG. 1 is a flowchart illustrating a method of manufacturing a thin film by using an atomic layer deposition (ALD) method according to some embodiments;

FIG. 2 is a timing diagram illustrating a method of manufacturing a thin film by using the ALD method of FIG. 1;

FIG. 3A, FIG. 3B, FIG. 3C, FIG. 3D, FIG. 3E, and FIG. 3F are cross-sectional views sequentially illustrating a method of manufacturing a thin film by using an ALD method according to some embodiments;

FIG. 4 is a graph comparing, with a comparative example, a growth rate of a thin film in a method of manufacturing a thin film according to some embodiments;

FIG. 5A and FIG. 5B are X-ray photoelectron spectroscopy (XPS) graphs comparing, with a comparative example, the ratio of elements constituting a thin film in a method of manufacturing a thin film according to some embodiments;

FIG. 6A and FIG. 6B are XPS graphs comparing, with a comparative example, the ratio of elements and vacancies constituting a thin film in a method of manufacturing a thin film according to some embodiments;

FIG. 7 is a cross-sectional view illustrating a semiconductor device according to some embodiments;

FIG. 8, FIG. 9 and FIG. 10 are cross-sectional views sequentially illustrating a method of manufacturing a semiconductor device by using an ALD method according to some embodiments;

FIG. 11A, FIG. 11B, and FIG. 11C are graphs comparing, with a comparative example, the electrical characteristics of a semiconductor device manufactured using an ALD method according to some embodiments;

FIG. 12 is a layout diagram illustrating a semiconductor device according to some embodiments;

FIG. 13 is an enlarged view of a portion of a cell array region of FIG. 12;

FIG. 14 is a cross-sectional view taken along line A1-A1′ of FIG. 12; and

FIG. 15, FIG. 16, FIG. 17, FIG. 18, FIG. 19, FIG. 20, FIG. 21, FIG. 22, FIG. 23, FIG. 24, and FIG. 25 are cross-sectional views illustrating a sequential process of a method of manufacturing a semiconductor device according to some embodiments.

### DETAILED DESCRIPTION OF THE EMBODIMENTS

Hereinafter, embodiments are described in detail with reference to the accompanying drawings. The like reference numerals are used for like components in the drawing, and redundant descriptions thereof are omitted.

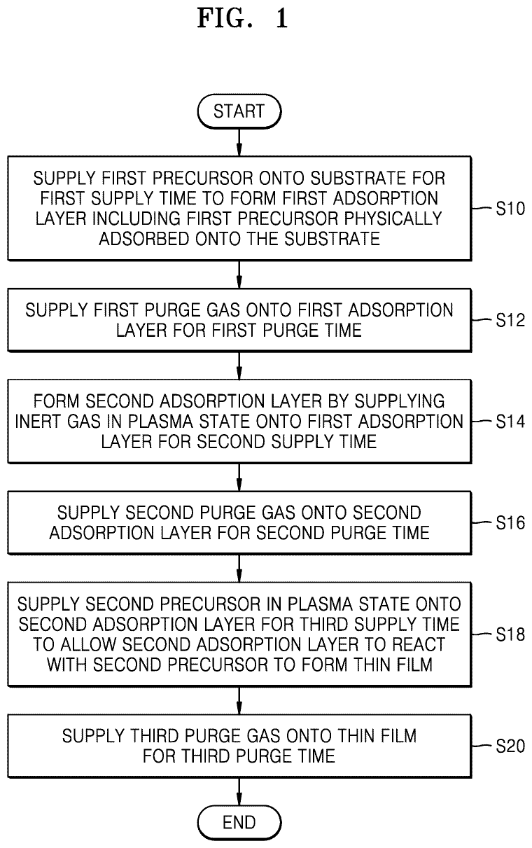

FIG. 1 is a flowchart illustrating a method of manufacturing a thin film by using an atomic layer deposition (ALD) method according to some embodiments.

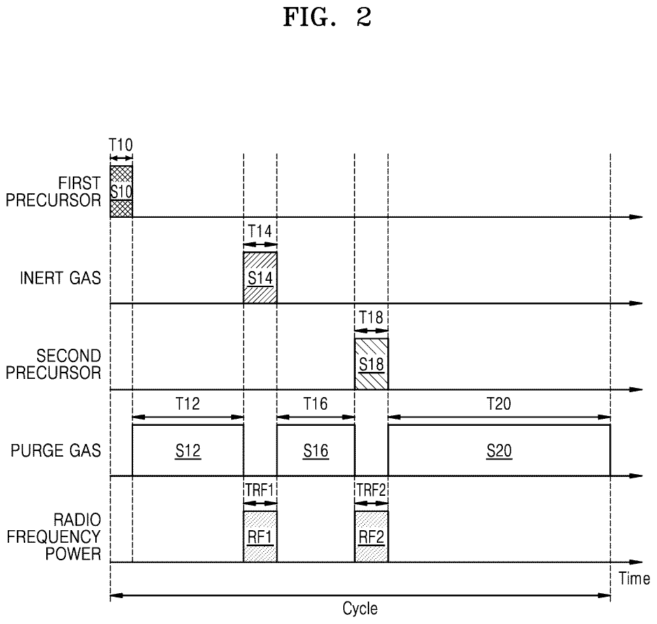

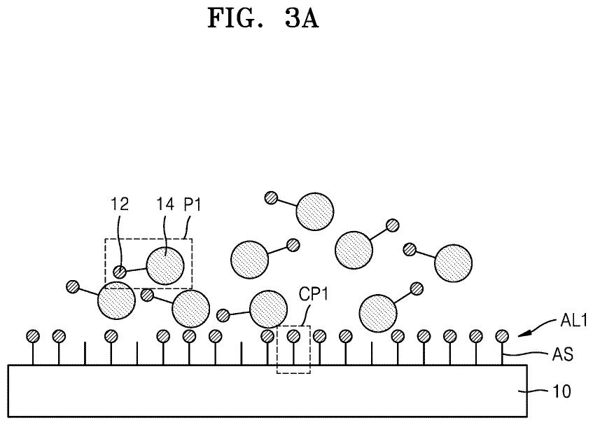

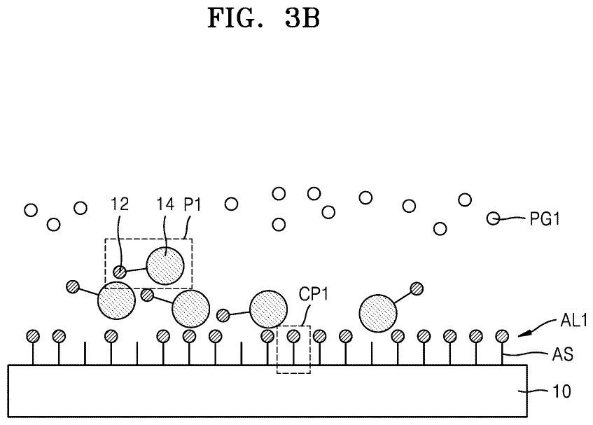

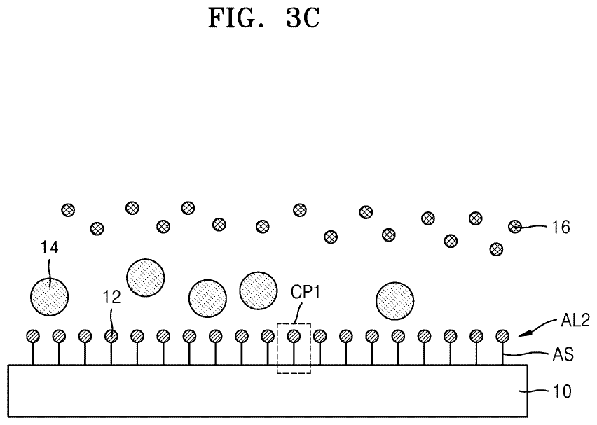

FIG. 2 is a timing diagram illustrating a method of manufacturing a thin film by using the ALD method of FIG. 1.

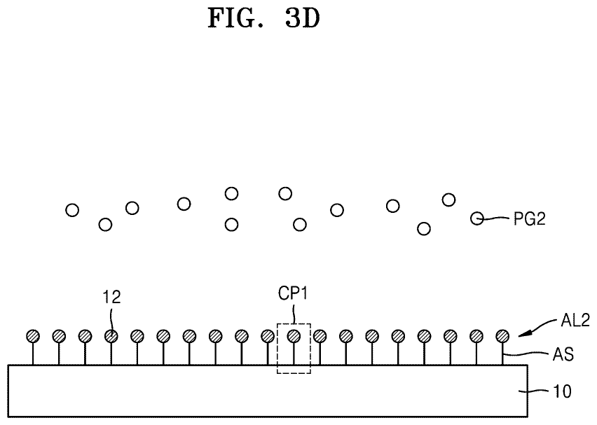

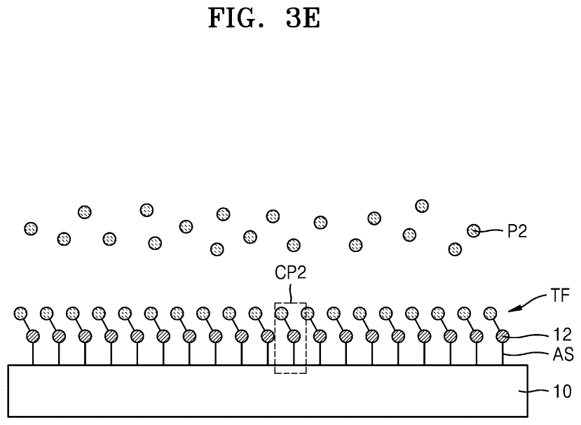

FIG. 3A, FIG. 3B, FIG. 3C, FIG. 3D, FIG. 3E, and FIG. 3F are cross-sectional views sequentially illustrating a method of manufacturing a thin film by using an ALD method according to some embodiments.

Hereinafter, a method of manufacturing a thin film by using an ALD method according to some embodiments is described in detail.

Referring to FIG. 1, FIG. 2 and FIG. 3A, an operation (S10) of supplying a metal precursor P1 onto a substrate 10 for a first supply time T10 to form a first adsorption layer AL1 including the metal precursor P1 physically adsorbed onto the substrate 10 may be performed.

As illustrated in FIG. 2, the first supply time T10 for supplying the metal precursor P1 onto the substrate 10 during the first supply time T10 may be relatively short. For example, the first supply time T10 may be a time corresponding to a pseudo-saturation period of the metal precursor P1. If the first supply time T10 corresponds to an undersaturation period of the metal precursor P1, the metal precursor P1 may not be provided at a concentration required for chemical adsorption. If the first supply time T10 corresponds to a full saturation period, the metal precursor P1 may be supplied excessively, which may be economically disadvantageous. For example, the first supply time T10 may be within 0.5 seconds to 4.5 seconds, within 0.5 seconds to 2.5 seconds, or within 0.5 seconds to 1.5 seconds. Because the first supply time T10 is relatively short, unnecessary oversupply of the metal precursor P1 may be suppressed, thereby reducing precursor consumption.

As illustrated in FIG. 3A, the substrate 10 may include a semiconductor element, such as silicon (Si), germanium (Ge), or a compound semiconductor, such as silicon carbide (SiC), gallium arsenide (GaAs), indium arsenide (InAs), and indium phosphide (InP). In some other embodiments, the substrate 10 may include a semiconductor substrate and structures including at least one insulating film formed on the semiconductor substrate or at least one conductive region. The conductive region may include, for example, an impurity-doped well or an impurity-doped structure. The substrate 10 may be provided within a reaction space, for example, within a reaction chamber.

The operation (S10) of forming the first adsorption layer AL1 including the metal precursor P1 may be performed, while maintaining the temperature of the substrate 10 at about 50 to 250 degrees Celsius or about 100 to 200 degrees Celsius. If the temperature of the substrate 10 is maintained too low, the ALD reaction on the substrate 10 may not occur easily, and if the temperature of the substrate 10 is maintained too high, the ALD reaction may not occur easily due to thermal decomposition. Unless otherwise specified in the operations below, the temperature of the substrate 10 may be maintained within about 50 to 250 degrees Celsius or within about 100 to 200 degrees Celsius.

In addition, the operation (S10) of forming the first adsorption layer AL1 including the metal precursor P1 may be performed, while maintaining the process pressure within the reaction chamber at about 0.1 Torr to about 100 Torr, preferably about 0.5 Torr to about 5 Torr. Unless otherwise specified in the operations below, the process pressure within the reaction chamber may be maintained at about 0.1 Torr to about 100 Torr, preferably about 0.5 Torr to about 5 Torr.

The metal precursor P1 may include a metal atom 12, and for example, the metal atom 12 may be any one selected from the group consisting of titanium (Ti), iron (Fe), cobalt (Co), copper (Cu), zinc (Zn), gallium (Ga), germanium (Ge), arsenic (As), yttrium (Y), zirconium (Zr), indium (In), tin (Sn), antimony (Sb), hafnium (Hf), tantalum (Ta), and tungsten (W).

The metal precursor P1 may include at least one ligand bonded to the metal atom 12. For example, depending on the oxidation number and coordination number of the metal atom 12, 1 to 6 or 2 to 4 ligands may be bonded to the metal atom 12.

In some embodiments, the at least one ligand may include at least one first ligand (bulky ligand, 14). The term “first ligand” as used herein, unless otherwise defined, refers to a sterically bulky organic substituent and has the function of forming a coordination bond to a central metal atom to control the reactivity, volatility, and thermal stability of a metal precursor.

Although it is illustrated in the present specification that the metal atom 12 and one first ligand 14 are bonded together, this is for convenience of illustration, and the disclosure is not limited to the metal atom 12 and one first ligand 14 bonded together. For example, depending on the oxidation number and coordination number of the metal atom 12, one to six or two to four first ligands 14 may be bonded to the metal atom 12. Herein, ligands other than the first ligand 14 are not shown for convenience of illustration, and ligands other than the first ligand 14 may be referred to as “second ligands.”

In some embodiments, the first ligand 14 may include an alkylamido ligand including an alkylamido group, an alkoxide ligand including an alkoxide group, an aminoalkoxide ligand including both an amino group and an alkoxide group, or combinations thereof.

The alkylamido ligand is represented by the general formula —NR₁R₂, and here, R₁ and R₂ are each independently a straight-chain or branched-chain alkyl group having 1 to 8 carbon atoms. Examples of the branched-chain alkyl group may include an isopropyl group, a tert-butyl group, a sec-butyl group, a neopentyl group, etc. Examples of the alkylamido ligands include, but are not limited to, dimethylamido (—N(CH₃)₂), ethylmethylamido (—N(CH₃)(C₂H₅)), diethylamido (—N(C₂H₅)₂), diisopropylamido (—N(i-Pr)₂), di-tert-butylamido (—N(t-Bu)₂), etc.

The alkoxide ligand is represented by the general formula-OR, and here, R is a straight-chain or branched-chain alkyl group having 1 to 8 carbon atoms. Examples of the alkoxide ligands include, but are not limited to, methoxide (—OCH₃), ethoxide (—OC₂H₅), isopropoxide (—Oi-Pr), tert-butoxide (—Ot-Bu), 2,2-dimethylpropoxide (—Ot—Am), etc.

Examples of the aminoalkoxide ligands include, but are not limited to, dimethylamino-2-propoxide, diethylaminoethoxide, and diisopropylaminopropoxide.

In some embodiments, the metal precursor P1 may include any one selected from the group consisting of tetrakis(ethylmethylamido)hafnium (TEMAHf), bis(dimethylamino-2-propoxide)diethylindium (DADI), tetrakis(dimethylamido)titanium (TDMATi), dimethylaluminum isopropoxide (DMAl), tetrakis(ethylmethylamido)zirconium (TEMAZr), [tris(2,2,6,6-tetramethyl-3,5-heptanedionate) indium, In(thd)₃], [tris(tetramethylheptanedionate) indium, In(tmhd)₃], or [tris(di-isopropylamidinato) indium [tris(di-isopropylamidinato) indium, In (iPr2-amidinato)₃], [tris(2,2,6,6-tetramethyl-3,5-heptanedionate) gallium, Ga(thd)₃], [tris(tetramethylheptanedionate) gallium, Ga(tmhd)₃], [tris(di-isopropylamidinato) gallium, Ga(iPr₂-amidinato)₃], [bis(2,2,6,6-tetramethyl-3,5-heptanedionate) zinc, Zn(tmhd)₂], [bis(tetram ethylheptanedionate) zinc, Zn(thd)₂], and [bis(di-isopropylguanidinate) zinc, Zn(iPr₂-guanidinate)₂], but is not limited thereto.

When a plurality of metal precursors P1 are supplied onto the substrate 10, some of the plurality of metal precursors P1 may be chemically bonded to the surface of the substrate 10 through a chemical reaction between an active site (AS) of the substrate 10 and the metal precursor P1. Here, the chemical bonding may proceed by a ligand-exchange reaction between the ligand of the metal precursor P1 and a functional group (e.g., —OH group) present on the surface of the substrate 10, and a first chemisorbed molecule CP1 may be formed on the surface of the substrate 10. In addition, some of the plurality of metal precursors P1 that do not participate in the chemical reaction with the AS of the substrate 10 may be physically adsorbed on the surface of the substrate 10 by van der Waals forces, etc. Accordingly, the first adsorption layer AL1 including the first chemisorbed molecule CP1 chemically adsorbed on the substrate 10 and the physically adsorbed metal precursor P1 may be formed on the substrate 10.

Because the metal precursor P1 includes at least one first ligand 14 and is relatively sterically bulky, the access of the metal precursor P1 to the AS of the substrate 1 may be limited, which may induce a screening effect. This may result in a reduced probability of initiation of the chemical adsorption reaction and a reduced growth per cycle (GPC). In addition, a surface self-limiting reaction may proceed incompletely, resulting in the formation of an adsorption layer with a relatively large number of defects. In addition, if the first ligand 14 of the metal precursor P1 is incompletely removed in a subsequent purge process, the remaining first ligand 14-based impurities may be included in the adsorption layer, causing the reaction with a reactant gas to proceed incompletely.

Referring to FIG. 1, FIG. 2 and FIG. 3B, an operation (S12) of supplying a first purge gas PG1 onto the first adsorption layer AL1 during a first purge time T12 may be performed.

As illustrated in FIG. 2, the first purge time T12 may be relatively longer than the first supply time T10, and, for example, the first purge time T12 may be within about 2 to 8 seconds, or within about 3 to 7 seconds, or within about 4 to 6 seconds. Although FIG. 2 illustrates that the supply of the first purge gas PG1 is initiated at the moment when the supply of the metal precursor P1 is stopped, in some other embodiments, the first purge gas PG1 is used as a carrier gas of the metal precursor P1, and only the supply of the metal precursor P1 is stopped, and the supply of the first purge gas PG1 may continue to achieve purging within a reaction space.

As illustrated in FIG. 3B, the first purge gas PG1 may be supplied onto the surface of the substrate 10 to partially remove the metal precursor P1 that is not chemically adsorbed or physically adsorbed. As the first purge gas PG1, an inert gas, such as argon (Ar), helium (He), neon (Ne), or N2 gas may be used.

Even after supplying the first purge gas PG1, some physically adsorbed metal precursor P1 may remain.

Referring to FIG. 1, FIG. 2 and FIG. 3C, an operation (S14) of forming a second adsorption layer AL2 may be performed by supplying an inert gas 16 in a plasma state onto the first adsorption layer (AL1, see FIG. 3B) during a second supply time T14.

As illustrated in FIG. 2, the second supply time T14 may be relatively longer than the first supply time T10 and may be relatively shorter than the first purge time T12. For example, the second supply time T14 may be within about 0.5 seconds to about 4.5 seconds, within about 0.5 seconds to about 3 seconds, or within about 1 second to about 2 seconds. In FIG. 2, the supply of the first purge gas PG1 is shown to be stopped at the moment when the supply of the inert gas 16 is started. However, if the first purge gas PG1 is the same as the inert gas 16, the supply of the first purge gas PG1 may be the supply of the inert gas 16, and thus, the supply of the first purge gas PG1 may not be stopped and may continue with the supply of the inert gas 16.

By applying radio frequency (RF) power within the reaction space for a first RF power supply time RF1 that is the same as the second supply time T14, the inert gas 16 may be excited into a plasma state and the inert gas 16 may be supplied into the reaction space in a plasma state. In some embodiments, the plasma state of the inert gas 16 may be formed in an inductively coupled (ICP) or electrostatically coupled (CCP) manner. The RF power may be set in a range of about 30 W to 400 W or about 50 W to 300 W.

As shown in FIG. 3C, RF power may be applied to the inert gas 16 on the first adsorption layer AL1 to supply the inert gas 16 in a plasma state onto the surface of the substrate 10. The fact that the inert gas 16 is supplied in a plasma state may mean that the inert gas 16 is supplied in an ion state.

In some embodiments, the inert gas 16 may include helium (He). In some other embodiments, the inert gas 16 may include a mixed gas of helium (He) and argon (Ar). If the mass of the inert gas 16 is too large, the first chemisorbed molecule CP1 chemically adsorbed on the substrate 10 may be separated during ion bombardment. If the mass of the inert gas 16 is too small, it may be difficult to induce surface migration or rearrangement of the physically adsorbed metal precursor P1 during ion bombardment, thereby making it difficult to control the screening effect.

The inert gas 16 in a plasma state may collide with the physically adsorbed metal precursor P1 to induce surface migration and rearrangement and induce a chemical reaction between the concealed AS and the metal precursor P1. Accordingly, the second adsorption layer AL2 including a large number of first chemisorbed molecules CP1 may be formed. The number of first chemisorbed molecules CP1 in the second adsorption layer AL2 may be greater than the number of first chemisorbed molecules CP1 in the first adsorption layer AL1.

In some embodiments, the inert gas 16 in a plasma state may cleave a bond having a relatively low binding energy of the metal atom 12 in the first chemisorbed molecule CP1 to form a radical centered on the metal atom 12. For example, in the first chemisorbed molecule CP1, the bond between the metal atom 12 and the second ligand may be cleaved to form a radical centered on the metal atom 12. For example, the bond between the metal atom 12 and a methyl group may be cleaved to form a radical centered on the metal atom 12. For example, when the metal precursor P1 includes bis(dimethylamino-2-propoxide)diethylindium (DADI), the inert gas 16 in a plasma state may cleave the In—CH₃ bond in the first chemisorbed molecule CP1 to form an indium (In) centered radical.

Referring to FIG. 1, FIG. 2, and FIG. 3D, an operation (S16) of supplying a second purge gas PG2 onto the second adsorption layer AL2 during a second purge time T16 may be performed.

As illustrated in FIG. 2, the second purge time T16 may be relatively longer than the second supply time T14 and may be, for example, within about 0.5 seconds to about 6.5 seconds, within about 1.5 seconds to about 5.5 seconds, or within about 2.5 seconds to about 4.5 seconds. Although FIG. 2 illustrates that the supply of the second purge gas PG2 starts at the moment when the supply of the inert gas 16 is stopped. However, if the second purge gas PG2 is the same as the inert gas 16, the supply of the second purge gas PG2 is the supply of the inert gas 16, and thus, the supply of the inert gas 16 may continue without interruption as the supply of the second purge gas PG2 to achieve the purge within the reaction space.

As illustrated in FIG. 3D, by supplying the second purge gas PG2 onto the surface of the substrate 10, a material separated from the metal precursor P1 shown in FIG. 3C, for example, the first ligand 14 separated from the metal precursor P1, may be removed. As the second purge gas PG2, an inert gas, such as argon (Ar), helium (He), neon (Ne), or N2 gas, may be used.

Referring to FIG. 1, FIG. 2 and FIG. 3E, an operation (S18) may be performed in which a reactant gas P2 is supplied in a plasma state onto the second adsorption layer AL2 during a third supply time T18 so that the second adsorption layer AL2 reacts with the reactant gas P2 to form a thin film (TF).

As illustrated in FIG. 2, the third supply time T18 may be relatively longer than the first supply time T10 and may be relatively shorter than the first purge time T12 and the second purge time T16. For example, the third supply time T18 may be within about 0.5 seconds to about 4.5 seconds, within about 0.5 seconds to about 3 seconds, or within about 1 second to about 2 seconds.

By applying RF power within the reaction space for a second RF power supply time RF2 that is the same as the third supply time T18, the reactant gas P2 may be excited into a plasma state so as to be supplied into the reaction space in the plasma state. The RF power may be set in a range of about 30 W to about 400 W or about 50 W to about 300 W.

As illustrated in FIG. 3E, by applying RF power to the reactant gas P2 on the second adsorption layer AL2, the reactant gas P2 may be supplied to the surface of the substrate 10 in a plasma state. Supplying the reactant gas P2 in a plasma state may refer to supplying the reactant gas P2 in an ion state.

In some embodiments, the reactant gas P2 may include an oxidizing agent. For example, the reactant gas P2 may be at least one selected from oxygen (O₂) and ozone (O₃). In some other embodiments, the reactant gas P2 may include a reducing agent. For example, the reactant gas P2 may be at least one selected from hydrogen (H₂), silane (SiH₄), ammonia (NH₃), and diborane (B₂H₆). The first chemisorbed molecule CP1 of the second adsorption layer AL2 may react with the reactant gas P2, and other ligands bonded to the metal atom 12 of the first chemisorbed molecule CP1 may be separated to form a second chemisorbed molecule CP2. In this manner, a TF including a plurality of second chemisorbed molecules CP2 may be formed. The TF may be a metal oxide film or a metal film.

In some embodiments, when a radical centered on the metal atom 12 is formed by supplying the inert gas 16 in a plasma state, the first chemisorbed molecule CP1 of the second adsorption layer AL2 may have relatively high reactivity toward the reactant gas P2.

Referring to FIG. 1, FIG. 2 and FIG. 3F, an operation (S20) of supplying a third purge gas PG3 onto the TF during a third purge time T20 may be performed.

As illustrated in FIG. 2, the third purge time T20 may be relatively longer than the third supply time T18 and may be, for example, within about 7 to about 13 seconds, within about 8 to about 12 seconds, or within about 9 to about 11 seconds.

As shown in FIG. 3F, the third purge gas PG3 may be supplied onto the surface of the substrate 10 to remove remaining impurities and unreacted reactant gas P2. As the third purge gas PG3, an inert gas, such as argon (Ar), helium (He), neon (Ne), or N2 gas, may be used.

In embodiments, the operations indicated as “S10,” “S12,” “S14,” “S16,” “S18,” and “S20” in FIG. 1 may constitute one cycle, and a TF may be formed through a cycle including the operations indicated as “S10,” “S12,” “S14,” “S16,” “S18,” and “S20,” and the cycle may be repeated several times so that the thin film is obtained with a desired thickness.

According to embodiments, even though the first supply time T10 of the metal precursor P1 is performed relatively short, within 0.5 to 4.5 seconds, stable thin film growth characteristics may be implemented by introducing the operation of supplying the inert gas 16 in a plasma state after the supply of the metal precursor P1 and before the supply of the reactant gas P2. In addition, the overall process time per cycle is shortened, thereby improving throughput and increasing process efficiency in mass-production.

In addition, even though the metal precursor P1 includes the first ligand 14 that is relatively sterically bulky, by introducing the operation of supplying the inert gas 16 in a plasma state after the supply of the metal precursor P1 and before the supply of the reactant gas P2, a screening effect caused by the first ligand 14 may be reduced, thereby increasing the GPC and reducing various impurities generated in the reaction of separating the first ligand 14 from the metal atom 12, and because the surface self-limiting reaction proceeds relatively completely, an adsorption layer with relatively few defects may be formed, and a TF with improved film quality may be provided even without an additional heat treatment process. In addition, a semiconductor device may be manufactured using a TF manufactured through a manufacturing process according to embodiments, and the manufactured semiconductor device may have improved electrical characteristics.

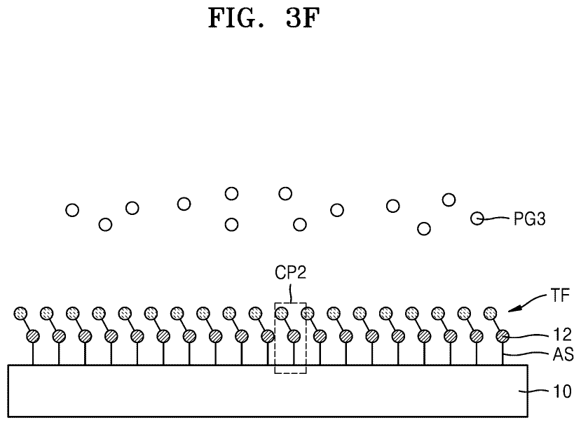

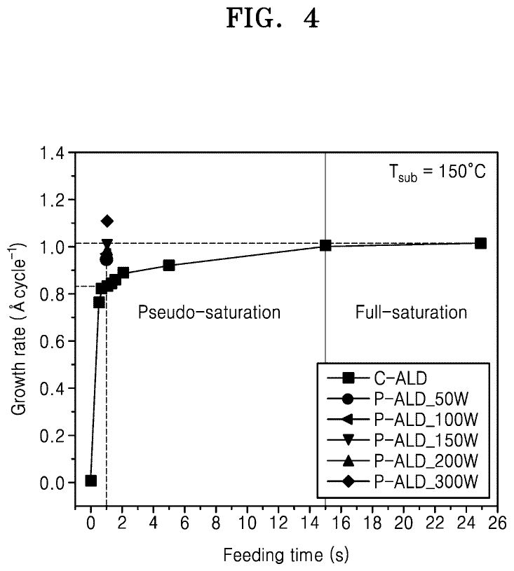

FIG. 4 is a graph comparing the growth rate of a TF in a method of manufacturing a TF according to some embodiments with a comparative example.

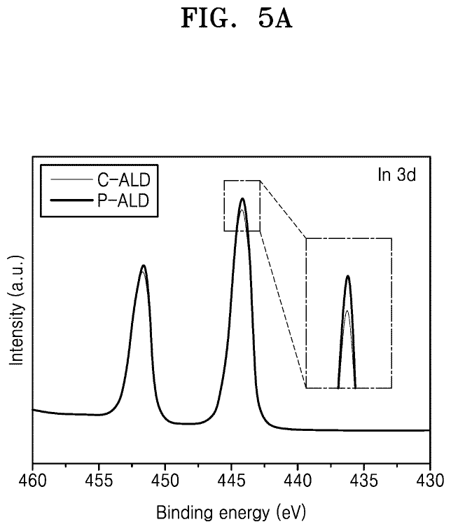

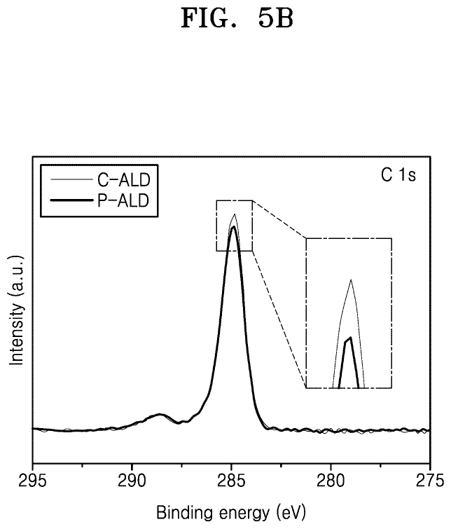

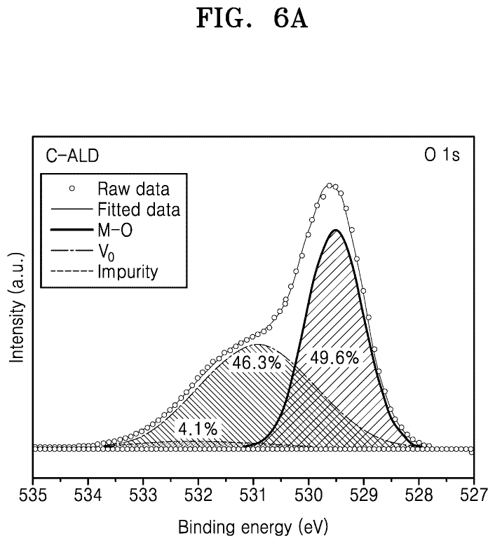

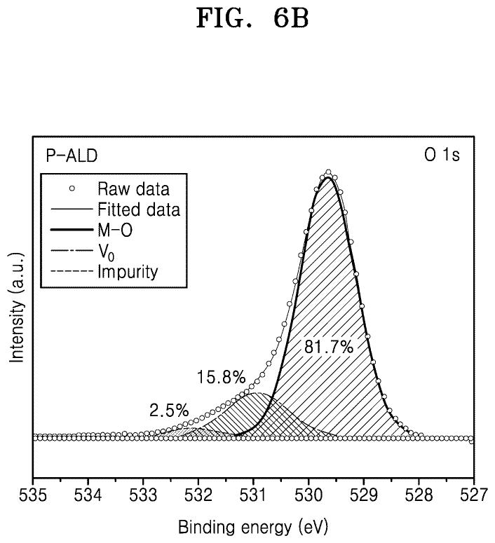

FIG. 5A and FIG. 5B are X-ray photoelectron spectroscopy (XPS) graphs comparing the ratio of elements constituting a thin film in a method of manufacturing a thin film according to some embodiments with a comparative example.

FIG. 6A and FIG. 6B are XPS graphs comparing the ratio of elements and vacancies constituting a thin film in a method of manufacturing a thin film according to some embodiments with a comparative example.

Hereinafter, an experimental example in which an indium oxide thin film (In₂O₃) is manufactured using bis(dimethylamino-2-propoxide)diethylindium (DADI) as a metal precursor and an oxidizing agent as a reactant gas and helium is supplied in a plasma state after supplying the metal precursor and before supplying the reactant gas is compared with a comparative example in which an indium oxide thin film (In₂O₃) is manufactured using bis(dimethylamino-2-propoxide)diethylindium as a metal precursor and an oxidizing agent as a reactant gas with reference to the graphs of FIG. 4, FIG. 5A, FIG. 5B, FIG. 6A, and FIG. 6B. The experimental example is indicated as “P-ALD” in each drawing, and the comparative example is indicated as “C-ALD” in each drawing.

Referring to FIG. 4, it can be seen that, when the metal precursor is supplied for about 1 second, the experimental example shows a higher GPC than the comparative example. In the experimental example, when the metal precursor is supplied for about 1 second and helium is supplied in a plasma state at a power of about 50 W to about 300 W, the GPC is close to 1, and therefore, in order to achieve a GPC close to 1, the metal precursor may need to be supplied for a relatively short time. In the comparative example, when the metal precursor was supplied for about 10 to about 20 seconds, the GPC was close to 1, and thus, in the comparative example, in order to achieve a GPC close to 1, the metal precursor may need to be supplied for a longer period of time. Therefore, in the experimental example, a higher GPC may be achieved by supplying the metal precursor for a relatively short period of time, thereby reducing the overall process time per cycle and improving economic efficiency.

Referring to FIG. 5A and FIG. 5B, in the experimental example, while the temperature of the substrate was maintained at about 150 degrees Celsius, a metal precursor was supplied for about 1 second, a first purge was performed for about 5 seconds, helium was supplied in a plasma state for about 1.5 seconds, a second purge was performed for about 3.5 seconds, a reactant gas was supplied for about 1.5 seconds, and a third purge was performed for about 10 seconds. In the comparative example, while maintaining the temperature of the substrate at about 150 degrees Celsius, the metal precursor was supplied for about 1 second, the first purge was performed for about 10 seconds, the reactant gas was supplied for about 1.5 seconds, and the second purge was performed for about 10 seconds.

In the experimental example, it can be seen that the intensity of the indium (In 3D) peak is relatively higher than that of the comparative example, while the intensity of the carbon (C1s) peak is relatively weaker. It may be inferred that, by introducing the process of supplying helium in a plasma state, the metal precursors physically adsorbed on the surface of the substrate were desorbed, and relatively more chemical bonds were formed between the metal precursors and the substrate. In addition, it may be inferred that the helium in a plasma state partially dissociated the ligands bound to indium to form indium-centered radicals, thereby enhancing reactivity toward the reactant gas (e.g., oxidizing agent).

Referring to FIG. 6A and FIG. 6B, the analysis of the oxygen (O 1s) spectra of the experimental example and comparative example reveals that the ratio of the defect peak due to oxygen vacancies (V₀) was 46.3% in the comparative example but decreased to 15.8% in the experimental example, and the ratio of metal-oxygen (M-O) lattice bond peak increased from 49.6% in the comparative example to 81.7% in the experimental example. That is, it can be seen that, by introducing the process of supplying helium in a plasma state, a film may be manufactured with a relatively high purity without additional heat treatment.

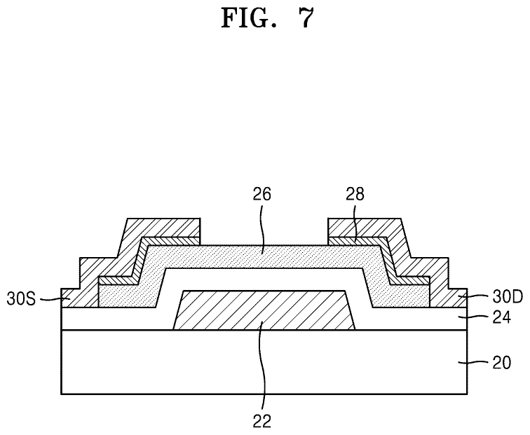

FIG. 7 is a cross-sectional view illustrating a semiconductor device according to some embodiments.

Referring to FIG. 7, a substrate 20 may be provided. The substrate 20 may be a semiconductor, metal, glass or polymer substrate. A gate electrode 22 extending in one direction may be formed on the substrate 20. The gate electrode 22 may be formed using Al, Cr, Cu, Ta, Ti, Mo, W, or alloys thereof. A gate insulating film 24 may be formed on the gate electrode 22. The gate insulating film 24 may include a silicon oxide film, a silicon oxynitride film, an aluminum oxide film, an aluminum oxynitride film, or a composite film thereof. The thickness of the gate electrode 22 and the gate insulating film 24 may each be formed to a thickness of several to several hundred nm, for example, a thickness of about 10 to about 300 nm, about 10 to about 200 nm, or about 10 to about 30 nm.

A metal oxide channel layer 26 patterned to cross an upper portion of the gate electrode 22 may be formed on the gate insulating film 24. The metal oxide channel layer 26 may include, for example, an In—Ga oxide layer, an In—Zn oxide layer, or an In—Ga—Zn oxide layer and may be in an amorphous state as deposited or patterned. The metal oxide channel layer 26 may be formed to a thickness of several to several hundred nm, for example, about 10 to about 300 nm, about 10 to about 200 nm, or about 10 to about 30 nm.

The metal oxide channel layer 26 may be formed using, for example, an ALD method. Specifically, the metal oxide channel layer 26 may be deposited through a process similar to the ALD method described above with reference to FIG. 1, FIG. 2, FIG. 3A, FIG. 3B, FIG. 3C, FIG. 3D, FIG. 3E, and FIG. 3F. For example, in the ALD method, an indium (In) source and an oxidizing agent, a gallium (Ga) source and/or a zinc (Zn) source may be used.

In addition, as an oxidizing agent, for example, at least one of oxygen (O₂), ozone (O₃), water vapor (H₂O), N₂O, and CO₂ may be used. When the metal oxide channel layer 26 is In—Ga—Zn oxide (IGZO), In may have about 20 to about 80 at %, for example, about 30 to about 70 at %, relative to the total number of atoms of In, Ga, and Zn. Within this range, In—Ga—Zn oxide (IGZO) may exhibit semiconductor properties. As an example, the atomic ratio of In:Ga:Zn may be 1:1:1 or 2:2:1.

By forming a source electrode 30S and a drain electrode 30D on opposite ends of the metal oxide channel layer 26, a portion of the surface of the metal oxide channel layer 26, for example, a region in which the metal oxide channel layer 26 overlaps the gate electrode 22, may be exposed between the source electrode 30S and the drain electrode 30D. The source electrode 30S and the drain electrode 30D may be formed using at least one metal selected from the group consisting of aluminum (Al), neodymium (Nd), silver (Ag), chromium (Cr), titanium (Ti), tantalum (Ta), and molybdenum (Mo), an alloy thereof, or a metal oxide conductive film (for example, indium tin oxide (ITO)).

In some embodiments, an ohmic contact layer 28 may be further provided between the metal oxide channel layer 26 and the source electrode 30S and between the metal oxide channel layer 26 and the drain electrode 30D. The ohmic contact layer 28 may include a conductive oxide layer having a lower oxygen content than the metal oxide channel layer 26. The ohmic contact layer 28 may lower contact resistance between the metal oxide channel layer 26 and the source electrode 30S and drain electrode 30D and prevents charge carriers from escaping the metal oxide channel layer 26. In some other embodiments, the ohmic contact layer 28 may be omitted.

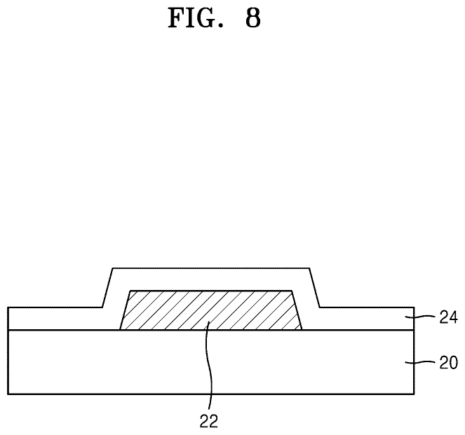

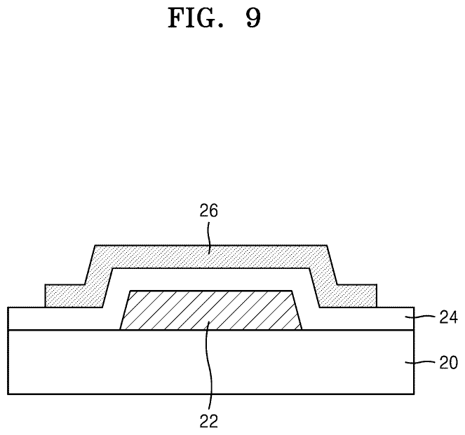

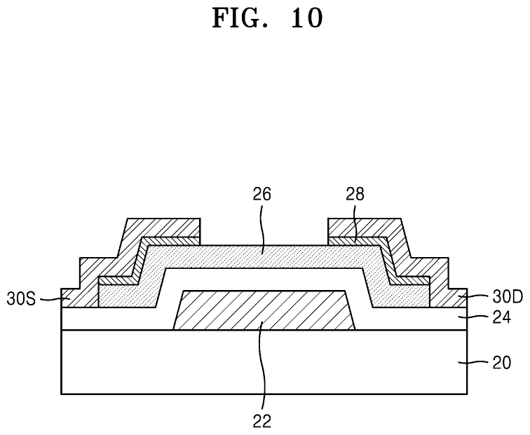

FIG. 8, FIG. 9, and FIG. 10 are cross-sectional views sequentially illustrating a method of manufacturing a semiconductor device using an ALD method according to some embodiments.

Referring to FIG. 8, the gate electrode 22 may be formed on the substrate 20, and a gate insulating film 24 covering the gate electrode 22 may be formed. The gate electrode 22 and the gate insulating film 24 may be formed using various methods used in the art, for example, a physical deposition method, such as sputtering, or a chemical deposition method, such as chemical vapor deposition or ALD.

Referring to FIG. 9, the metal oxide channel layer 26 may be formed on the gate insulating film 24. The metal oxide channel layer 26 may be deposited through a process similar to the ALD method described above with reference to FIG. 1, FIG. 2, FIG. 3A, FIG. 3B, FIG. 3C, FIG. 3D, FIG. 3E, and FIG. 3F.

In some embodiments, a first cycle including the operations of supplying a first metal precursor including one selected from an indium source, a gallium source, and a zinc source, performing a purge process by supplying a first purge gas, supplying an inert gas in a plasma state, performing a purge process by supplying a second purge gas, supplying a reactant gas including an oxidizing agent, and performing a purge process by supplying a third purge gas may be repeatedly performed. The first metal precursor may include a first ligand that is sterically bulky. In other words, at least one of the indium source, the gallium source and the zinc source as the first metal precursor may include a first ligand that is sterically bulky.

In some other embodiments, a second cycle including the operations of supplying a second metal precursor including one selected from an indium source, a gallium source, and a zinc source, performing a purge process by supplying a first purge gas, supplying a reactant gas including an oxidizing agent, and performing a purge process by supplying a second purge gas may be performed repeatedly together with the first cycle. The second metal precursor may include only a second ligand that is relatively sterically small. In other words, the second metal precursor may not include the first ligand. As the second metal precursor, at least one of the indium source, the gallium source and the zinc source may include only the second ligand that is relatively sterically small.

The composition ratio of indium, gallium, and zinc in the formed TF film may be adjusted by adjusting each of the number of cycles using the indium source as a precursor, the gallium source as a precursor, and the zinc source as a precursor.

In embodiments, the indium source may be at least one selected from [tris(2,2,6,6-tetramethyl-3,5-heptanedionate) indium (In(thd)₃)], [tris(tetramethylheptanedionate) indium (In(tmhd)₃)], or [tris(di-isopropylamidinato) indium (In(iPr₂-amidinato)₃)], and bis(dimethylamino-2-propoxide)diethylindium (DADI). The gallium source may be at least one selected from [tris(2,2,6,6-tetramethyl-3,5-heptanedionate) gallium, Ga(thd)₃], tris(tetramethylheptanedionate) gallium, Ga(tmhd)₃], and [tris(di-isopropylamidinato) gallium, Ga(iPr₂-amidinato)₃]. The zinc source may be at least one selected from [bis(2,2,6,6-tetramethyl-3,5-heptanedionate) zinc, Zn(tmhd)₂], [bis(tetram ethylheptanedionate) zinc, Zn(thd)₂], and [bis(di-isopropylguanidinate) zinc, Zn(iPr2-guanidinate)₂]. However, this is merely an example, and the indium source, the gallium source, and the zinc source are not limited to those described above, and any precursor including a ligand that is relatively sterically bulky may be employed as an embodiment.

Referring to FIG. 10, in order to form the source electrode 30S and the drain electrode 30D on the metal oxide channel layer 26, a metal layer (not shown) may be formed on the metal oxide channel layer 26 and then patterned using a mask (not shown). The metal layer may include any one of a Mo single metal layer, a multi-metal layer including a Mo layer, a metal layer including Ti, and a metal layer including Cr, or a silicide including Pt, Cu, Al, W, MoW, AlNd, Ni, Ag, Au, IZO, and ITO, or any one thereof.

When an ohmic contact layer is not formed during the process of forming the source electrode 30S and the drain electrode 30D, an annealing process may be performed subsequently. A reaction may occur between the metal oxide channel layer 26 and the source electrode 30S and drain electrode 30D through the subsequent annealing process, and as a result, an ohmic contact layer 28 may be formed.

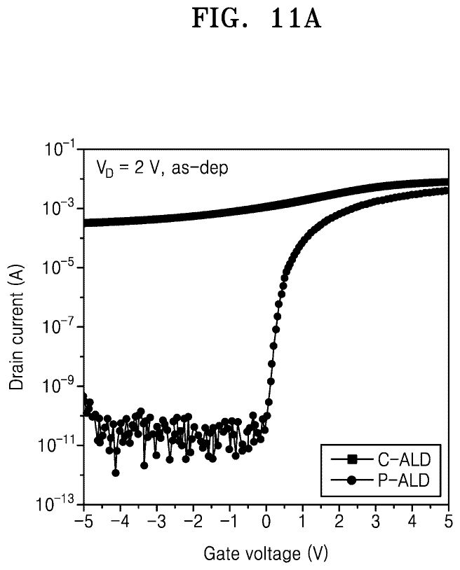

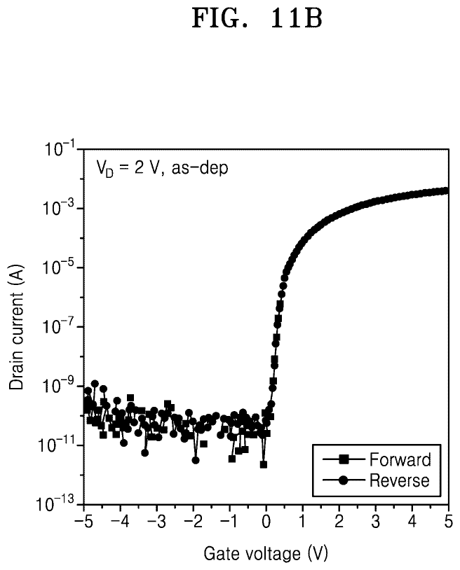

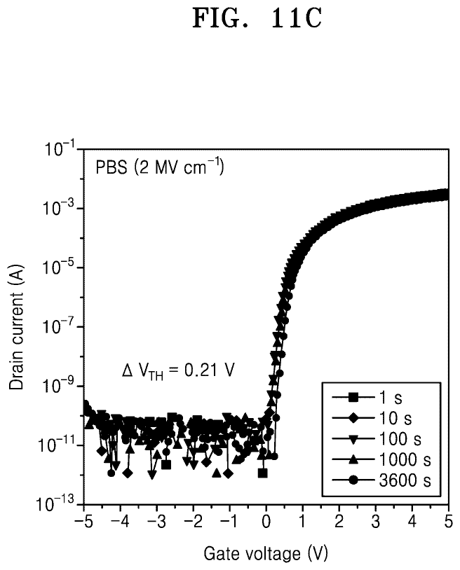

FIG. 11A, FIG. 11B, and FIG. 11C are graphs comparing the electrical characteristics of a semiconductor device manufactured using an ALD method according to some embodiments with a comparative example.

Hereinafter, in an experimental example in which an IGZO thin film transistor is manufactured by repeating a cycle of using one selected from an indium source, a gallium source, and a zinc source as a metal precursor and using an oxidizing agent as a reactant gas, but helium is supplied in a plasma state at a power of 200 W before supplying the reactant gas after supplying the metal precursor and in a comparative example in which an IGZO thin film transistor is manufactured by repeating a cycle of using one selected from an indium source, a gallium source, and a zinc source as a metal precursor and using an oxidizing agent as a reactant gas, the electrical characteristics of each thin film transistor are compared with reference to the graphs of FIG. 11A, FIG. 11B, and FIG. 11C. Bis(dimethylamino-2-propoxide)diethylindium (DADI) was used as the indium source. Experimental examples are indicated as “P-ALD” in each drawing, and comparative examples are indicated as “C-ALD” in each drawing.

Referring to FIG. 11A, in current-voltage characteristic measurement results, in the case of the comparative example, no asymmetry of the current is observed according to a change in the polarity of an applied voltage, and thus, no rectifying behavior is observed. However, in the case of the experimental example, it can be seen that a rectifying behavior is observed in which the magnitude of the current significantly changes depending on the direction of an applied voltage. In the experimental example, the ratio of ON current to OFF current (ON/OFF current ratio) was measured to be approximately 109 or more. In addition, it can be seen that a field-effect mobility of 60 cm² V⁻¹s⁻¹ was observed, demonstrating excellent carrier mobility properties.

Referring to FIG. 11B, in the case of the experimental example, the current-voltage characteristics were measured under both forward bias and reverse bias conditions, and a hysteresis phenomenon was relatively less observed compared to the comparative example. These results indicate that charge trapping or detrapping phenomena are suppressed at the interface between the gate insulating film and the channel layer and indicate that the transistor according to the disclosure has excellent interfacial stability. In the experimental example, despite the change in electrical driving conditions, a threshold voltage shift of the device was relatively small compared to the comparative example, which is presumed to be a result of maintaining a low interface trap density during the gate voltage application and removal process.

Referring to FIG. 11C, the results of a stress test performed for 1 hour under conditions of a gate electric field of 2 MV/cm are shown to evaluate bias stability. In the experimental example, a threshold voltage shift (ΔVₜₕ) was only about 0.21 V, which may be interpreted as indicating that the device characteristics are stably maintained even under long-term electrical operation. That is, this suggests that charge traps rarely occur at the interface between the gate insulating film and the channel layer.

In summary of the results of FIG. 11A, FIG. 11B, and FIG. 11C, it can be seen that the experimental example may stably implement the rectifying operation compared to the comparative example, has excellent long-term reliability, reduces performance degradation due to repeated driving, and has excellent bias stress immunity, resulting in relatively excellent electrical characteristics. The effect of improving electrical characteristics may be confirmed simply by adding the process of supplying inert gas in a plasma state without an additional heat treatment process.

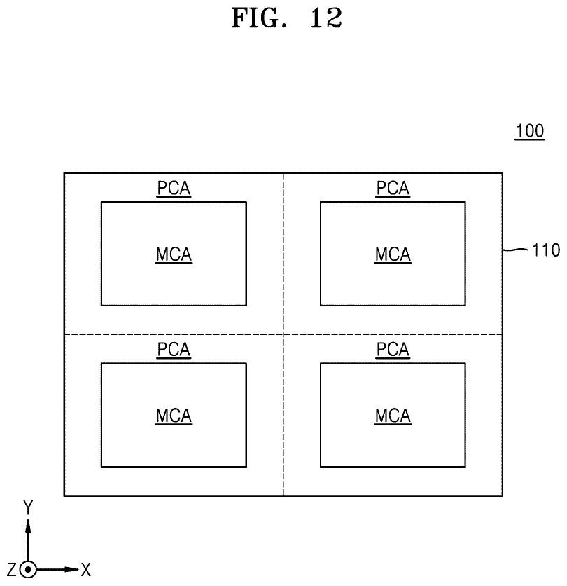

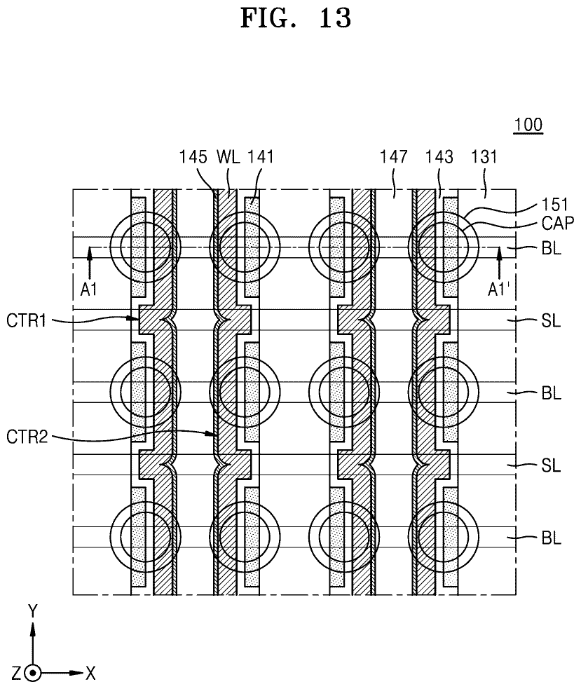

FIG. 12 is a layout diagram illustrating a semiconductor device 100 according to some embodiments.

Referring to FIG. 12, the semiconductor device 100 may include a substrate 110 including a cell array region MCA and a peripheral circuit region PCA. In embodiments, the cell array region MCA may be a memory cell region of a DRAM device, and the peripheral circuit region PCA may be a core region or a peripheral circuit region of the DRAM device. For example, the peripheral circuit region PCA may include a peripheral circuit transistor (not shown) for delivering a signal and/or power to a memory cell array included in the cell array region MCA. In embodiments, the peripheral circuit transistor (not shown) may constitute various circuits, such as a command decoder, a control logic, an address buffer, a row decoder, a column decoder, a sense amplifier, and a data input/output circuit.

The cell array region MCA is arranged on the substrate 110, and the peripheral circuit region PCA is arranged adjacent thereto. However, the arrangement relationship between the cell array region MCA and the peripheral circuit region PCA is not limited thereto, and the peripheral circuit region PCA may be arranged on the substrate 110, and the cell array region MCA may be arranged on the peripheral circuit region PCA.

Herein, a direction in which the substrate 110 extends may be defined as a first horizontal direction (the X direction), a direction intersecting the first horizontal direction (the X direction) may be defined as a second horizontal direction (the Y direction), and a direction perpendicular to the upper surface of the substrate 110 may be defined as a vertical direction (the Z direction).

FIG. 13 is an enlarged view of a portion of the cell array region MCA of FIG. 12.

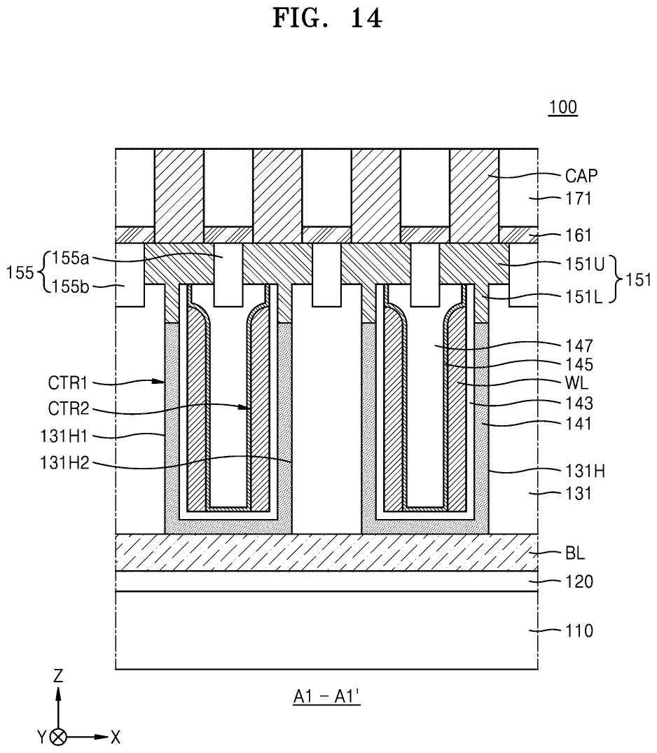

FIG. 14 is a cross-sectional view taken along line A1-A1′ of FIG. 12.

Referring to FIG. 13 and FIG. 14, the semiconductor device 100 may include the substrate 110, a lower insulating layer 120, a plurality of bit lines BL and a plurality of shield lines SL disposed on the lower insulating layer 120.

In embodiments, the substrate 110 may include a Si semiconductor, such as single crystal silicon, polycrystalline silicon, or amorphous silicon. Alternatively, the substrate 110 may include a Ge semiconductor or a compound semiconductor, such as SiGe, SiC, GaAs, InAs, InGaAs, or InP. The terms “SiGe,” “SiC,” “GaAs,” “InAs,” “InGaAs,” and “InP” used herein refer to materials including the elements included in each term and are not chemical formulas representing stoichiometric relationships. The substrate 110 may include a conductive region, for example, an impurity-doped well or an impurity-doped structure.

The lower insulating layer 120 may be placed on the substrate 110. The lower insulating layer 120 may extend in the first horizontal direction (the X direction) and the second horizontal direction (the Y direction) along the extension direction of the substrate 110. The lower insulating layer 120 may include an oxide film, a nitride film, or combinations thereof.

The plurality of bit lines BL and the plurality of shield lines SL extending in the first horizontal direction (the X direction) may each be arranged on the lower insulating layer 120. The plurality of bit lines BL and the plurality of shield lines SL may be arranged apart from each other in the second horizontal direction (the Y direction), and the plurality of bit lines BL and the plurality of shield lines SL may be arranged alternately with each other, respectively. For example, one shield line SL may be placed between two adjacent bit lines BL.

In embodiments, the plurality of bit lines BL may include Ti, TiN, Ta, TaN, W, WN, TiSiN, WSiN, polysilicon, or combinations thereof. For example, the plurality of bit lines BL may include a conductive layer (not shown) and a conductive barrier layer (not shown) disposed on the upper and lower surfaces of the conductive layer. In embodiments, the plurality of shield lines SL may each include, but are not limited to, W, Al, Cu, or combinations thereof. In embodiments, the plurality of shield lines SL may each include a conductive film including W, Al, Cu, or combinations thereof and an air gap or void within the conductive film.

A bit line insulating layer (not shown) may be located between one bit line BL selected from the plurality of bit lines BL and an adjacent shield line SL. The bit line insulating layer may extend in the first horizontal direction (the X direction) along the extension direction of the bit line BL and surround opposite sidewalls of the bit line BL in the second horizontal direction (the Y direction). In other words, the bit line insulating layer may extend in the first horizontal direction (the X direction) along the extension direction of the shield line SL and surround opposite sidewalls of the shield line SL in the second horizontal direction (the Y direction). For example, the bit line insulating layer may be formed at the same level as that of the plurality of bit lines BL by filling a space between a selected one of the plurality of bit lines BL and an adjacent shield line SL.

A mold layer 131 may be placed on the plurality of bit lines BL, the plurality of shield lines SL, and the bit line insulating layer. The mold layer 131 may extend in the vertical direction (the Z direction) on the plurality of bit lines BL and the bit line insulating layer. The mold layer 131 may include at least one of silicon oxide, silicon nitride, and silicon oxynitride. The mold layer 131 may include a plurality of mold openings 131H. The plurality of mold openings 131H may have a first sidewall 131H1 and a second sidewall 131H2 that are opposite to each other. An upper surface of the bit line BL may be exposed from the bottom of each of the plurality of mold openings 131H.

A plurality of channel layers 141 may be arranged on the plurality of bit lines BL, the plurality of shield lines SL, and the bit line insulating layer. Each of the plurality of channel layers 141 may extend conformally along an inner wall of the plurality of mold openings 131H. Accordingly, an outer wall of each of the plurality of channel layers 141 may be in contact with the mold layer 131. The channel layer 141 may include a portion extending along the bottom of the mold opening 131H and a portion extending in the vertical direction (the Z direction) along the first sidewall 131H1 and the second sidewall 131H2 of the mold opening 131H. The bottom of the channel layer 141 may be in contact with an upper surface of the bit line BL exposed from the bottom of the mold opening 131H, and an upper surface of the channel layer 141 may be in contact with a conductive contact pattern 151. Here, the upper surface of the channel layer 141 may be placed at a lower level in the vertical direction (the Z direction) than the upper surface of the mold layer 131.

In embodiments, the channel layer 141 may include an oxide semiconductor material. For example, the oxide semiconductor material may include at least one metal element selected from indium (In), gallium (Ga), and zinc (Zn) and may include at least one of, for example, IGZO (InGaZnOx), Sn-doped IGZO (Sn-doped InGaZnOx), W-doped IGZO (W-doped InGaZnOx), and IZO (InZnOx). In embodiments, the channel layer 141 may be formed by a process similar to the ALD process described above with reference to FIG. 1, FIG. 2, FIG. 3A, FIG. 3B, FIG. 3C, FIG. 3D, FIG. 3E, and FIG. 3F. The metal precursor supplied in the ALD process for forming the channel layer 141 may include the first ligand that is relatively sterically bulky, such as the metal precursor described above with reference to FIG. 1, FIG. 2, FIG. 3A, FIG. 3B, FIG. 3C, FIG. 3D, FIG. 3E, and FIG. 3F.

A gate insulating layer 143 may be placed on the inner wall of a plurality of channel layers 141. For example, the gate insulating layer 143 may be conformally arranged on the inner wall of the channel layer 141. The bottom of the gate insulating layer 143 may extend discontinuously along the bottom of the channel layer 141 to partially expose the channel layer 141.

The gate insulating layer 143 may include at least one selected from a high-k dielectric material and a ferroelectric material having a higher dielectric constant than silicon oxide. In embodiments, the gate insulating layer 143 may include at least one selected from hafnium oxide (HfO₂), hafnium silicate (HfSiO), hafnium oxynitride (HfON), hafnium silicon oxynitride (HfSiON), lanthanum oxide (La₂O₃), lanthanum aluminum oxide (LaAlO), zirconium oxide (ZrO₂), zirconium silicate (ZrSiO), zirconium oxynitride (ZrON), zirconium silicon oxynitride (ZrSiON), tantalum oxide (Ta₂O₅), titanium oxide (TiO₂), barium strontium titanium oxide (BaSrTiO₃, BST), barium titanium oxide (BaTiO₃, BTO), lead zirconate titanate (PZT), strontium bismuth tantalate (SBT), bismuth iron oxide (BFO), strontium titanium oxide (SrTiO₃, STO), yttrium oxide (Y₂O₃), aluminum oxide (Al₂O₃), or lead scandium tantalum oxide (PbScTaO).

A word line WL may be arranged on the inner wall of the gate insulating layer 143. For example, the word line WL may be conformally arranged along the inner wall of the gate insulating layer 143. In embodiments, the upper surface of the word line WL may be arranged at a different level in the vertical direction (the Z direction) from the upper surface of the gate insulating layer 143. The upper surface of the word line WL may be arranged at a lower level in the vertical direction (the Z direction) than the upper surface of the gate insulating layer 143. A portion of the upper surface of the word line WL adjacent to the gate insulating layer 143 may be arranged at a higher level in the vertical direction (the Z direction) than other portions of the upper surface of the word line WL. Accordingly, the upper surface of the word line WL may have a profile of a slope having a higher level in the vertical direction (the Z direction) toward the gate insulating layer 143. The bottom of the word line WL may extend discontinuously along the bottom of the channel layer 141 to partially expose the channel layer 141. In embodiments, the word line WL may include Ti, TiN, Ta, TaN, W, WN, TiSiN, WSiN, polysilicon, or combinations thereof.

One mold opening 131H may include a plurality of gate insulating layers 143 and a plurality of word lines WL. For example, one mold opening 131H may include two gate insulating layers 143 apart from each other and two word lines WL apart from each other. One of the gate insulating layers 143 apart from each other may be arranged to face the first sidewall 131H1 of the mold opening 131H, and the other gate insulating layer 143 may be arranged to face the second sidewall 131H2 of the mold opening 131H. One word line WL among the spaced word lines WL may be arranged to face the first sidewall 131H1 of the mold opening 131H, and the other word line WL may be arranged to face the second sidewall 131H2 of the mold opening 131H. Here, the one gate insulating layer 143, the one word line WL, and the channel layer 141 portion in contact with the one gate insulating layer 143 may constitute a first cell transistor CTR1. In addition, the other gate insulating layer 143, the other word line WL, and the channel layer 141 portion in contact with the other gate insulating layer 143 may constitute a second cell transistor CTR2. Accordingly, the first cell transistor CTR1 and the second cell transistor CTR2 may be arranged in a mirror-symmetrical shape within one mold opening 131H.

An insulating liner 145 may be placed on the inner wall of the word line WL. The insulating liner 145 may conformally extend along the inner wall of the word line WL and the inner wall of a portion of the gate insulating layer 143 that is not covered with the word line WL. An insulating partition 147 may be placed on the insulating liner 145. The insulating partition 147 is placed between the first cell transistor CTR1 and the second cell transistor CTR2 to separate the first cell transistor CTR1 and the second cell transistor CTR2. The insulating partition 147 may fill a residual space within the mold opening 131H on the insulating liner 145.

In embodiments, the insulating liner 145 and the insulating partition 147 may include a silicon oxide film or a silicon nitride film. For example, the insulating liner 145 may include a silicon nitride film, and the insulating partition 147 may include a silicon oxide film.

A plurality of conductive contact patterns 151 may be arranged on the first cell transistor CTR1 and the second cell transistor CTR2. The plurality of conductive contact patterns 151 may be arranged in a regular array with a constant interval therebetween in the first horizontal direction (the X direction) and the second horizontal direction (the Y direction), as illustrated in FIG. 13.

An example in which the plurality of conductive contact patterns 151 are arranged in a matrix structure on a plane (e.g., the X-Y plane) on the substrate 110 is shown, but the technical idea of the disclosure is not limited thereto. For example, the plurality of conductive contact patterns 151 may be arranged in a honeycomb structure on the plane (e.g., the X-Y plane) on the substrate 110. The plurality of conductive contact patterns 151 may be mutually insulated by a isolation insulating film 155.

The plurality of conductive contact patterns 151 may cover the upper portion of the mold layer 131 and may extend to cover the upper portions of the first cell transistor CTR1 and the second cell transistor CTR2. Each of the plurality of conductive contact patterns 151 may be apart from the word line WL with the gate insulating layer 143 therebetween. Each of the plurality of conductive contact patterns 151 may include a lower contact portion 151L located between the gate insulating layer 143 and the mold layer 131 and an upper pad portion 151U disposed above the lower contact portion 151L and integrally connected to the lower contact portion 151L. The lower contact portion 151L of each of the plurality of conductive contact patterns 151 may have a sidewall facing the mold layer 131, a bottom surface in contact with the upper surface of the channel layer 141, and a sidewall facing the gate insulating layer 143. The upper pad portion 151U of each of the plurality of conductive contact patterns 151 may cover the upper surface of each of the mold layer 131, the gate insulating layer 143, the insulating liner 145, and the insulating partition 147.

In embodiments, the plurality of conductive contact patterns 151 may each include Ti, TiN, Ta, TaN, Mo, Ru, W, WN, TiSiN, WSiN, or combinations thereof. For example, the plurality of conductive contact patterns 151 may each include a stack structure of a conductive barrier film including TiN and a conductive film including W.

In embodiments, a vertical level of the upper surface of the channel layer 141 may be lower than the vertical levels of the upper surfaces of the mold layer 131, the gate insulating layer 143, the insulating liner 145, and the insulating partition 147. Herein, “vertical level” may refer to a distance from one surface of the substrate 110 in the vertical direction (the Z direction or −Z direction).

In order to electrically isolate the conductive contact pattern 151 connected to the first cell transistor CTR1 and the conductive contact pattern 151 connected to the second cell transistor CTR2, a plurality of isolation insulating films 155 may be arranged. The plurality of isolation insulating films 155 may include a first isolation insulating film 155a disposed on the insulating partition 147 and a second isolation insulating film 155b disposed on the mold layer 131. A lower portion of the sidewall of the first isolation insulating film 155a may be surrounded by the insulating partition 147, and an upper portion of the sidewall of the first isolation insulating film 155a may be surrounded by the conductive contact pattern 151. A lower portion of the sidewall of the second isolation insulating film 155b may be surrounded by the mold layer 131, and an upper portion of the sidewall of the second isolation insulating film 155b may be surrounded by the conductive contact pattern 151. In embodiments, the isolation insulating film 155 may include a silicon nitride film or a silicon oxide film.

An etch stop film 161 and an interlayer insulating film 171 may be sequentially stacked on the plurality of conductive contact patterns 151 and the isolation insulating film 155. A plurality of capacitor structures CAP may be arranged on the plurality of conductive contact patterns 151 and the isolation insulating film 155. The plurality of capacitor structures CAP may penetrate through the interlayer insulating film 171 and the etch stop film 161 in the vertical direction (the Z direction) to be connected to one conductive contact pattern 151 selected from a plurality of conductive contact patterns 151. In embodiments, the etch stop film 161 may include a silicon nitride film, and the interlayer insulating film 171 may include a silicon oxide film.

Generally, a cell transistor of a DRAM device has a buried channel array transistor (BCAT) structure that uses a portion of the silicon substrate as a channel region. However, as the integration of DRAM devices improves, the size of cell transistors also needs to be reduced, which causes leakage current from the channel region of the cell transistor to increase. According to embodiments of the technical idea of the disclosure, a significantly reduced leakage current may be achieved by forming a channel layer using an oxide semiconductor material, such as indium gallium zinc oxide.

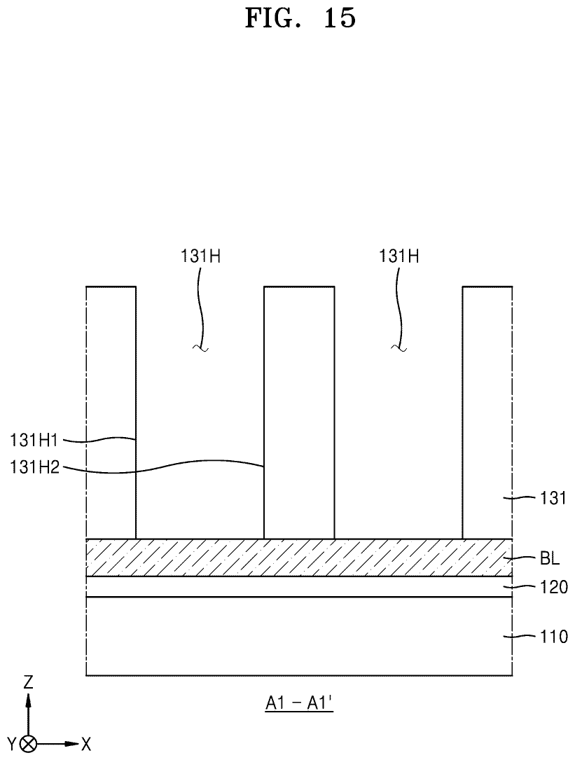

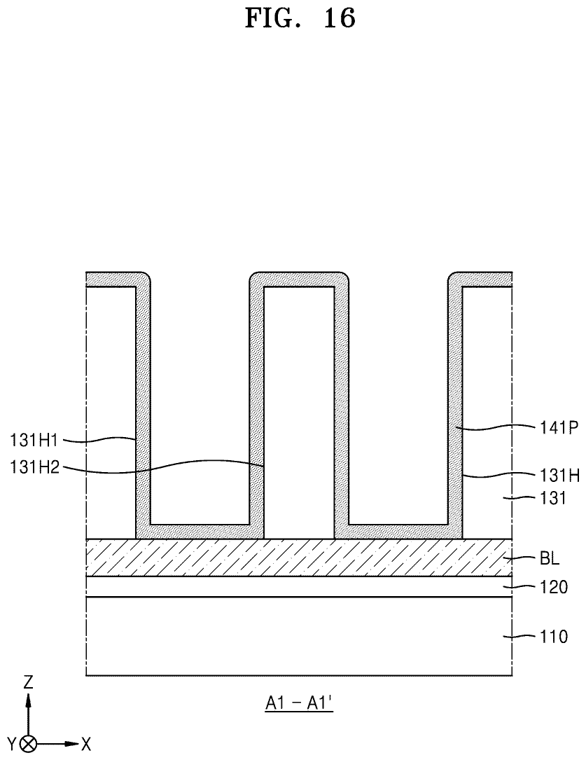

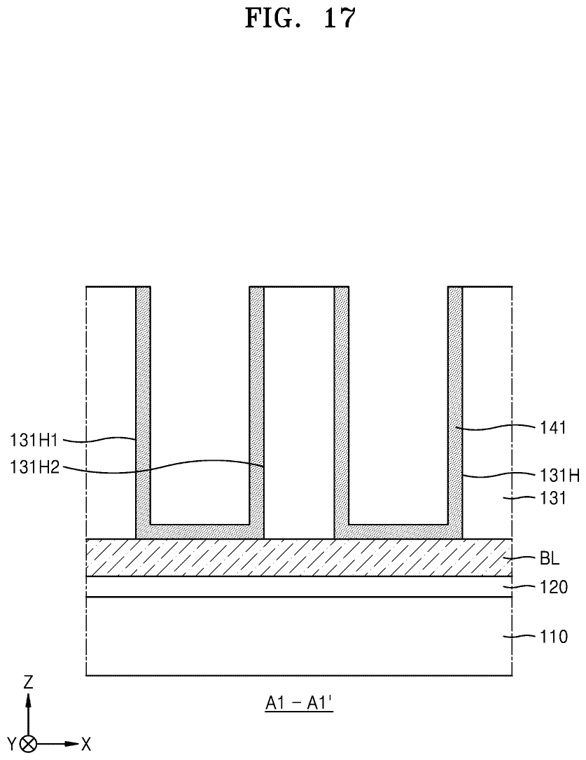

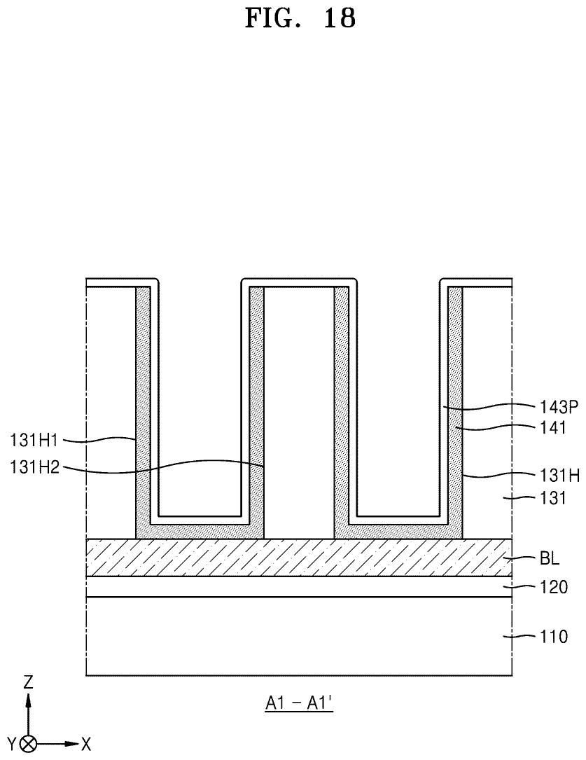

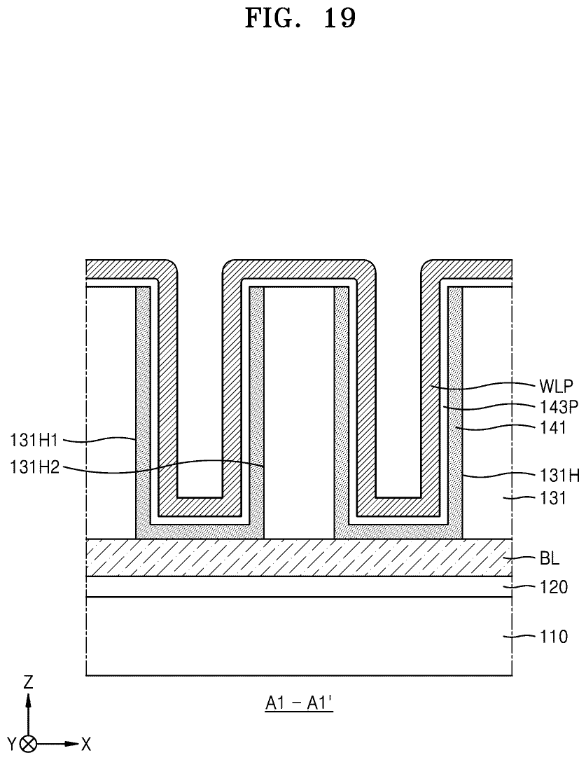

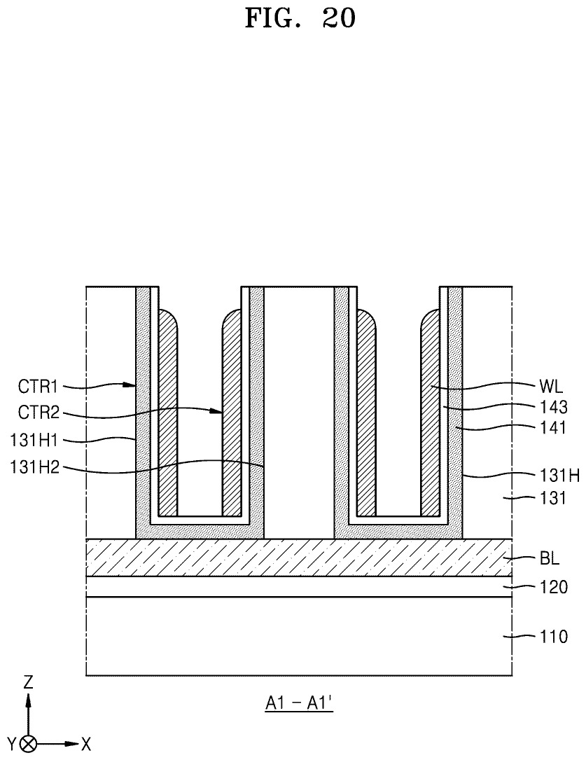

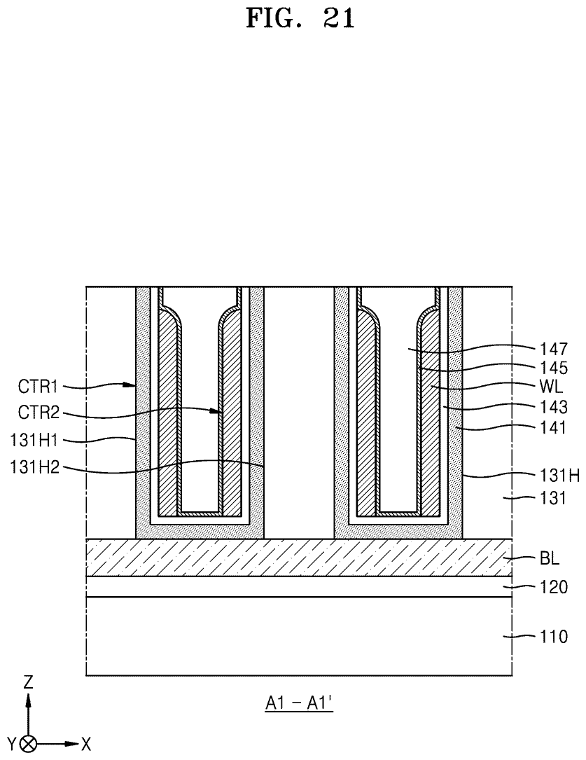

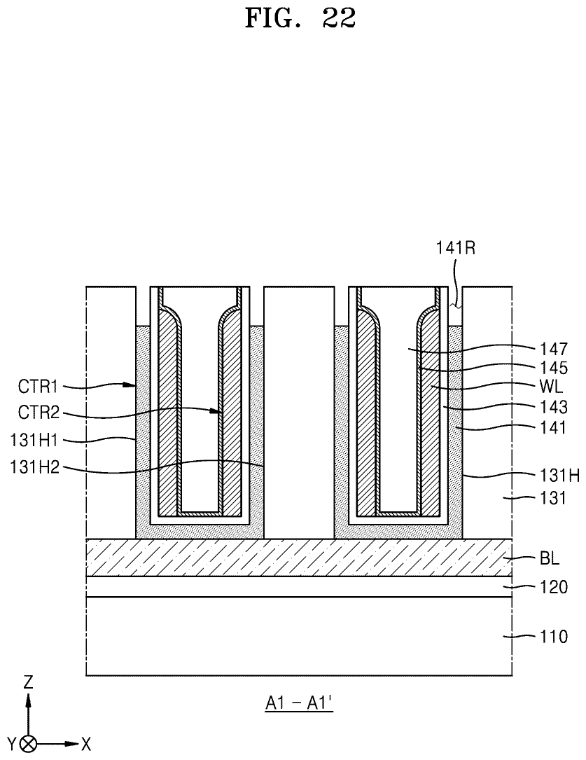

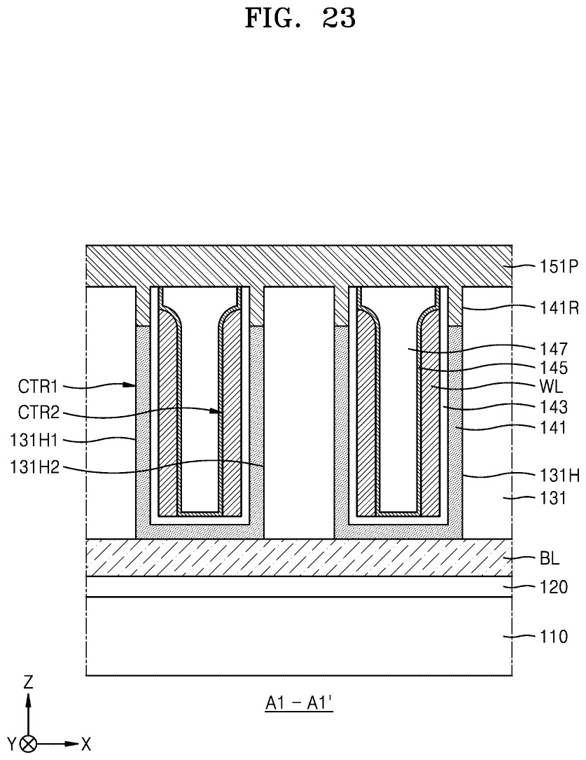

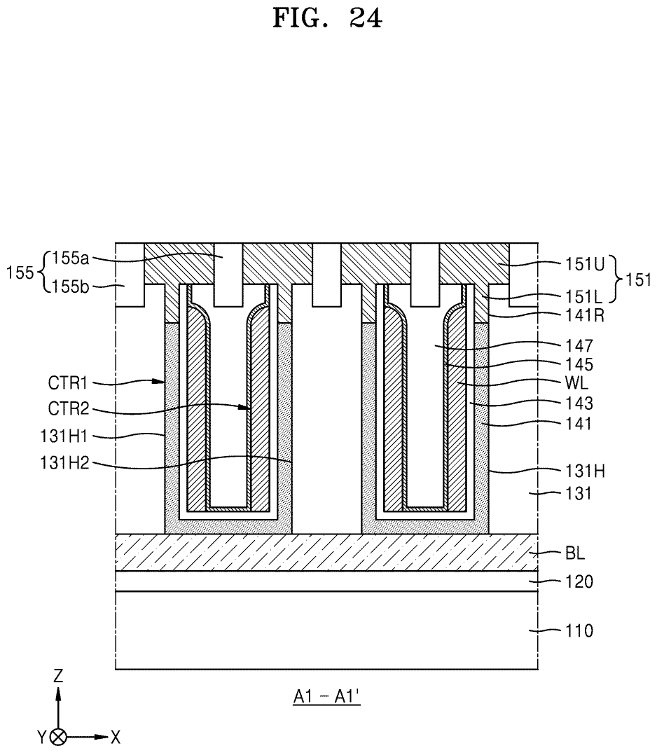

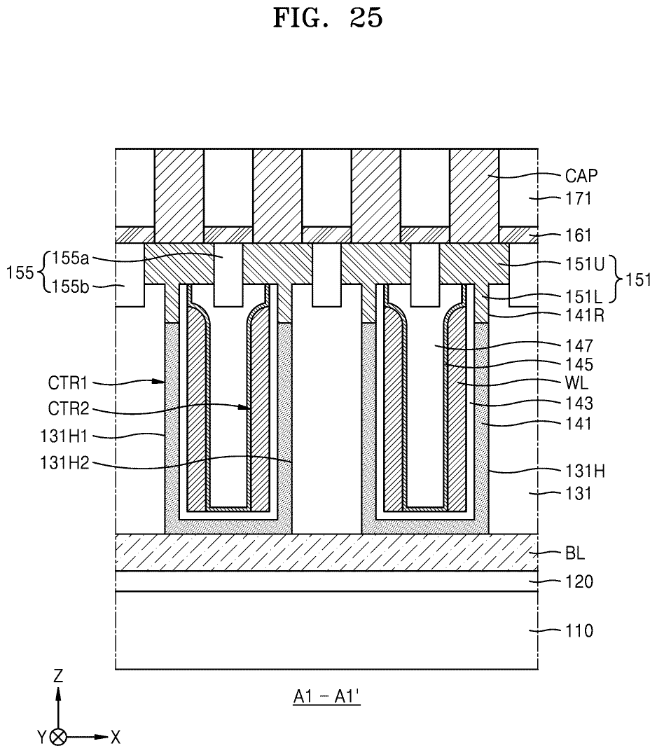

FIG. 15, FIG. 16, FIG. 17, FIG. 18, FIG. 19, FIG. 20, FIG. 21, FIG. 22, FIG. 23, FIG. 24, and FIG. 25 are cross-sectional views illustrating a method of manufacturing a semiconductor device according to some embodiments in accordance with a process sequence.

In FIG. 15, FIG. 16, FIG. 17, FIG. 18, FIG. 19, FIG. 20, FIG. 21, FIG. 22, FIG. 23, FIG. 24, and FIG. 25, the same reference numerals as in FIG. 13 and FIG. 14 may be understood to indicate the same components.

Referring to FIG. 15, the lower insulating layer 120 may be formed on the substrate 110. A plurality of bit lines BL and a plurality of shield lines SL extending in the first horizontal direction (the X direction) and apart in the second horizontal direction (the Y direction) on the lower insulating layer 120 and a bit line insulating layer (not shown) filling a space between a selected one of the plurality of bit lines BL and an adjacent shield line SL may be formed.

For example, the bit line insulating layer may be formed on the lower insulating layer 120 and patterned using a mask pattern (not shown) to form a bit line formation space (not shown), and a conductive material may be stacked within the bit line formation space. Thereafter, a plurality of bit lines BL may be formed by removing the upper side of the conductive material so that the upper surface of the bit line insulating layer is exposed. Similarly, the bit line insulating layer may be patterned using a mask pattern to form a shield line formation space (not shown), and a conductive material may be stacked within the shield line formation space. Thereafter, the upper side of the conductive material may be removed so that the upper surface of the bit line insulating layer is exposed to form a plurality of shield lines SL (in FIG. 13).

In embodiments, each of the plurality of bit lines BL and the plurality of shield lines SL may include a lower conductive barrier layer (not shown), a conductive layer (not shown), and an upper conductive barrier layer (not shown) that are sequentially stacked. For example, the bit line insulating layer may be formed on the lower insulating layer 120 and patterned using a mask pattern to form a bit line formation space, and a lower conductive barrier layer, a conductive layer, and a conductive barrier layer may be sequentially formed within the bit line formation space. Thereafter, a plurality of bit lines BL may be formed by removing the conductive barrier layer, the conductive layer, and the upper side of the conductive barrier layer so that the upper surface of the bit line insulating layer is exposed. Similarly, for example, a shield line formation space may be formed by patterning the bit line insulating layer using a mask pattern, and a lower conductive barrier layer, a conductive layer, and a conductive barrier layer may be sequentially formed within the shield line formation space. Thereafter, a plurality of shield lines SL may be formed by removing the conductive barrier layer, the conductive layer, and the upper side of the conductive barrier layer so that the upper surface of the bit line insulating layer is exposed.

The mold layer 131 may be formed on the plurality of bit lines BL, the plurality of shield lines SL and bit line insulating layer (not shown). Although not shown, a lower etch stop film (not shown) including at least one of silicon oxide, silicon nitride, and silicon oxynitride may be formed on the plurality of shield lines SL and bit line insulating layer (not shown), and then the mold layer 131 may be formed on the lower etch stop film. The lower etch stop film may include a material having an etch selectivity, different from that of the mold layer 131.

Thereafter, a mask pattern (not shown) may be formed on the mold layer 131, and a plurality of mold openings 131H may be formed using the mask pattern as an etch mask. The upper surface of the bit line BL may be exposed at the bottom of the plurality of mold openings 131H. The plurality of mold openings 131H may include first sidewalls 130H1 and second sidewalls 130H2 that are opposed to each other.

Referring to FIG. 16, a preliminary channel layer 141P may be conformally formed on the mold layer 131 along the upper surface of the mold layer 131 and the inner wall of the mold opening 131H. The preliminary channel layer 141P may include an oxide semiconductor material. For example, the oxide semiconductor material may include at least one metal element selected from indium (In), gallium (Ga), and zinc (Zn) and may include at least one of, for example, IGZO (InGaZnOx), Sn-doped IGZO (Sn-doped InGaZnOx), W-doped IGZO (W-doped InGaZnOx), and IZO (InZnOx).

The preliminary channel layer 141P may be deposited through a process, similar to the ALD method described above with reference to FIG. 1, FIG. 2, FIG. 3A, FIG. 3B, FIG. 3C, FIG. 3D, FIG. 3E, and FIG. 3F.

In some embodiments, a first cycle including the operations of supplying a first metal precursor including one selected from an indium source, a gallium source, and a zinc source, performing a purge process by supplying a first purge gas, supplying an inert gas in a plasma state, performing a purge process by supplying a second purge gas, supplying a reactant gas including an oxidizing agent, and performing a purge process by supplying a third purge gas may be repeatedly performed. The first metal precursor may include a first ligand that is sterically bulky. In other words, at least one of the indium source, the gallium source and the zinc source as the first metal precursor may include a first ligand that is sterically bulky.

In some other embodiments, a second cycle including the operations of supplying a second metal precursor including one selected from an indium source, a gallium source, and a zinc source, performing a purge process by supplying a first purge gas, supplying a reactant gas including an oxidizing agent, and performing a purge process by supplying a second purge gas may be performed repeatedly together with the first cycle. The second metal precursor may include only a second ligand that is relatively sterically bulky. In other words, the second metal precursor may not include the first ligand. As the second metal precursor, at least one of the indium source, the gallium source and the zinc source may include only a second ligand that is relatively sterically small.

The composition ratio of indium, gallium, and zinc in the formed thin film may be controlled by adjusting the number of cycles using the indium source as a precursor, the gallium source as a precursor, and the zinc source as a precursor.

In embodiments, the indium source may be at least one selected from [tris(2,2,6,6-tetramethyl-3,5-heptanedionate) indium (In(thd)₃)], [tris(tetramethylheptanedionate) indium (In(tmhd)₃)], or [tris(di-isopropylamidinato) indium (In(iPr₂-amidinato)₃)], and bis(dimethylamino-2-propoxide)diethylindium (DADI). The gallium source may be at least one selected from [tris(2,2,6,6-tetramethyl-3,5-heptanedionate) gallium, Ga(thd)₃], tris(tetramethylheptanedionate) gallium, Ga(tmhd)₃], and [tris(di-isopropylamidinato) gallium, Ga(iPr₂-amidinato)₃]. The zinc source may be at least one selected from [bis(2,2,6,6-tetramethyl-3,5-heptanedionate) zinc, Zn(tmhd)₂], [bis(tetramethylheptanedionate) zinc, Zn(thd)₂], and [bis(di-isopropylguanidinate) zinc, Zn(iPr2-guanidinate)₂]. However, this is merely an example, and the indium source, the gallium source, and the zinc source are not limited to those described above, and any precursor including a ligand that is relatively sterically bulky may be employed as an embodiment.

Referring to FIG. 17, a sacrificial mold layer (not shown) may be formed on the preliminary channel layer 141P. The sacrificial mold layer (not shown) may be formed to cover the upper surface of the preliminary channel layer 141P and fill the interior of the mold opening 131H. The sacrificial mold layer (not shown) may include, for example, at least one of silicon oxide, silicon nitride, and silicon oxynitride.

Thereafter, the upper portion of the structure in which the sacrificial mold layer (not shown) is formed on the preliminary channel layer 141P may be removed, so that the mold layer 131, the preliminary channel layer 141P, and the sacrificial mold layer (not shown) inside the mold opening 131H may be exposed. A portion of the preliminary channel layer 141P covering the upper surface of the mold layer 131 may be removed, so that the channel layer 141 may be formed.

Thereafter, a process of removing the sacrificial mold layer (not shown) inside the exposed mold opening 131H may be performed. As a result, the sacrificial mold layer (not shown) inside the mold opening 131H may be removed, so that the channel layer 141 disposed on the bottom of the mold opening 131H may be exposed.

Referring to FIG. 18, a preliminary gate insulating layer 143P may be formed on the channel layer 141. The preliminary gate insulating layer 143P may be conformally formed along the upper surface of the mold layer 131 and the inner wall of the channel layer 141. The preliminary gate insulating layer 143P may include at least one selected from a high-k dielectric material and a ferroelectric material having a dielectric constant higher than silicon oxide. In embodiments, the preliminary gate insulating layer 143P may include at least one selected from hafnium oxide (HfO₂), hafnium silicate (HfSiO), hafnium oxynitride (HfON), hafnium silicon oxynitride (HfSiON), lanthanum oxide (La₂O₃), lanthanum aluminum oxide (LaAlO), zirconium oxide (ZrO₂), zirconium silicate (ZrSiO), zirconium oxynitride (ZrON), zirconium silicon oxynitride (ZrSiON), tantalum oxide (Ta₂O₅), titanium oxide (TiO₂), barium strontium titanium oxide (BaSrTiO₃, BST), barium titanium oxide (BaTiO₃, BTO), lead zirconate titanate (PZT), strontium bismuth tantalate (SBT), bismuth iron oxide (BFO), strontium titanium oxide (SrTiO₃, STO), yttrium oxide (Y₂O₃), aluminum oxide (Al₂O₃), or lead scandium tantalum oxide (PbScTaO).

Referring to FIG. 19, a preliminary word line WLP may be formed on the preliminary gate insulating layer 143P. The preliminary word line WLP may be conformally formed along the preliminary gate insulating layer 143P. The preliminary word line WLP may be formed using Ti, TiN, Ta, TaN, W, WN, TiSiN, WSiN, polysilicon, or combinations thereof.

Referring to FIG. 20, an etching process may be performed on the preliminary word line WLP to remove the preliminary word line WLP portion disposed on the upper surface of the mold layer 131 and the preliminary word line WLP portion disposed on the bottom of the mold opening 131H and leave the preliminary word line WLP portion disposed on each of the first sidewall 131H1 and the second sidewall 131H2 of the mold opening 131H. Accordingly, the preliminary word line WLP may be separated into two word lines WL respectively disposed on the first sidewall 131H1 and the second sidewall 131H2 of the mold opening 131H.

In addition, by the etching process, the preliminary gate insulating layer 143P portion disposed on the upper surface of the mold layer 131 may be removed and the preliminary gate insulating layer 143P portion disposed on the bottom of the mold opening 131H and the preliminary gate insulating layer 143P portion disposed on each of the first sidewall 131H1 and the second sidewall 131H2 of the mold opening 131H may be left. In embodiments, the upper surface of the preliminary gate insulating layer 143P portion disposed on each of the first sidewall 131H1 and the second sidewall 131H2 of the mold opening 131H may be formed at the same level as the upper surface of the channel layer 141 in the vertical direction (the Z direction). In other embodiments, although not shown, the upper surface of the preliminary gate insulating layer 143P portion disposed on each of the first sidewall 131H1 and the second sidewall 131H2 of the mold opening 131H may be formed at a lower level than the upper surface of the channel layer 141 in the vertical direction (the Z direction). Accordingly, the gate insulating layer 143 may be formed from the preliminary gate insulating layer 143P.

In embodiments, the etching process may be performed as an anisotropic etching process. Through the etching process, the preliminary word line WLP portion disposed on the bottom of the mold opening 131H is removed, so that the upper surface of the gate insulating layer 143 portion disposed on the bottom of the mold opening 131H may be exposed.

In other embodiments, through the etching process, not only the preliminary word line WLP portion disposed on the bottom of the mold opening 131H, but also the preliminary gate insulating layer 143P portion disposed on the bottom of the mold opening 131H may be removed. In this case, the upper surface of the channel layer 141 portion disposed on the bottom of the mold opening 131H may be exposed.

Referring to FIG. 21, the insulating liner 145 conformally covering the inner walls of the plurality of word lines WL and the inner wall of the gate insulating layer 143 that are not covered by the plurality of word lines WL may be formed. Thereafter, the insulating partition 147 filling the internal space of the mold opening 131H in which the insulating liner 145 is formed may be formed inside the mold opening 131H in which the insulating liner 145 is formed.

In embodiments, the insulating liner 145 and the insulating partition 147 may include a silicon oxide film or a silicon nitride film. For example, the insulating liner 145 may include a silicon nitride film, and the insulating partition 147 may include a silicon oxide film.

Referring to FIG. 22, a recess process may be performed on the upper surface of the channel layer 141 to remove the upper portion of the channel layer 141. The recess process may be performed using a wet process, a dry process, or combinations thereof. Accordingly, a plurality of channel recess spaces 141R defined by the space between the sidewall of the gate insulating layer 143 and the sidewall of the mold layer 131 may be formed on the channel layer 141. Through the recess process, the upper surface of the channel layer 141 may be placed at a lower level than the upper surface of the mold layer 131 and the upper surface of the gate insulating layer 143 in the vertical direction (the Z direction).

Referring to FIG. 23, a preliminary conductive contact film 151P may be formed on the upper surface of the mold layer 131, the upper surface of the first cell transistor CTR1, and the upper surface of the second cell transistor CTR2. The preliminary conductive contact film 151P may extend to fill the plurality of channel recess spaces 141R and cover the upper surfaces of the mold layer 131, the gate insulating layer 143, the insulating liner 145, and the insulating partition 147. The preliminary conductive contact film 151P may include a stack structure of a conductive barrier film and a conductive film. In this case, the conductive barrier film may be conformally deposited on the upper surface of the first cell transistor CTR1 and the upper surface of the second cell transistor CTR2, and then the conductive film may be deposited on the conductive barrier film. In embodiments, the preliminary conductive contact film 151P may include Ti, TiN, Ta, TaN, W, WN, TiSiN, WSiN, polysilicon, or combinations thereof. For example, the preliminary conductive contact film 151P may include a stack structure of a conductive barrier film including TiN and a conductive film including W.

Referring to FIG. 24, a mask pattern (not shown) may be formed on the preliminary conductive contact film 151P of FIG. 23, and a portion of the preliminary conductive contact film 151P may be removed using the mask pattern to separate the preliminary conductive contact film 151P into a plurality of conductive contact patterns 151. The plurality of conductive contact patterns 151 may include the lower contact portion 151L filling a plurality of channel recess spaces 141R and the upper pad portion 151U disposed above the lower contact portion 151L and integrally connected to the lower contact portion 151L.

Thereafter, a plurality of isolation insulating films 155 may be formed within the region in which the preliminary conductive contact film 151P has been removed. In embodiments, the plurality of isolation insulating films 155 may include silicon nitride.

The plurality of isolation insulating films 155 may include a first isolation insulating film 155a and a second isolation insulating film 155b. The first isolation insulating film 155a may extend along the sidewall of the conductive contact pattern 151. The second isolation insulating film 155b may extend along the sidewall of the conductive contact pattern 151 and may penetrate through a portion of the mold layer 131.

Referring to FIG. 25, an upper etch stop film 161 may be formed on the conductive contact pattern 151 and the isolation insulating film 155. The etch stop film 161 and the interlayer insulating film 171 may be formed, and a plurality of capacitor structures CAP that penetrate through the etch stop film 161 and the interlayer insulating film 171 to be connected to the plurality of conductive contact patterns 151 may be formed.

As described above, the method of manufacturing the semiconductor device 100 has been described. However, various modifications and changes may be made within the scope of the technical idea of the disclosure to manufacture semiconductor devices having various structures from the descriptions given above with reference to FIG. 15, FIG. 16, FIG. 17, FIG. 18, FIG. 19, FIG. 20, FIG. 21, FIG. 22, FIG. 23, FIG. 24, and FIG. 25.

While the disclosure has been particularly shown and described with reference to embodiments thereof, it will be understood that various changes in form and details may be made therein without departing from the spirit and scope of the following claims.

What is claimed is:

1. A method of manufacturing a thin film by using an atomic layer deposition method including at least one cycle, wherein
the at least one cycle includes:
forming a first adsorption layer by supplying a metal precursor onto a substrate for a first supply time;
supplying a first purge gas onto the first adsorption layer for a first purge time;
forming a second adsorption layer by supplying an inert gas in a plasma state onto the first adsorption layer for a second supply time;
supplying a second purge gas onto the second adsorption layer for a second purge time;
supplying a reactant gas in a plasma state onto the second adsorption layer for a third supply time to allow the second adsorption layer to react with the reactant gas to form a thin film; and
supplying a third purge gas onto the thin film for a third purge time,
wherein the second supply time is longer than the first supply time.

2. The method of claim 1, wherein the reactant gas includes an oxidizing agent.

3. The method of claim 1, wherein the reactant gas is at least one selected from oxygen (O₂) and ozone (O₃).

4. The method of claim 1, wherein the metal precursor is any one selected from tetrakis(ethylmethylamido)hafnium (TEMAHf), bis(dimethylamino-2-propoxide)diethylindium (DADI), tetrakis(dimethylamido)titanium (TDMATi), dimethylaluminum isopropoxide (DMAI), and tetrakis(ethylmethylamido)zirconium (TEMAZr).

5. The method of claim 1, wherein the inert gas includes helium (He) or a mixed gas of helium (He) and argon (Ar).

6. The method of claim 1, wherein
the metal precursor includes a metal atom and a ligand coordinately bonded to the metal atom, and
in the supplying of the inert gas in a plasma state, the inert gas separates the ligand from the metal atom in the metal precursor of the first adsorption layer and forms a radical with the metal atom as a central atom.

7. The method of claim 1, wherein a temperature of the substrate is maintained within about 100° C. to about 200° C.

8. The method of claim 1, wherein, in the supplying of the inert gas in a plasma state, power of about 50 W to about 300 W is applied to the inert gas.

9. The method of claim 1, wherein the first supply time is about 0.5 seconds to about 4 seconds, the second supply time is about 0.5 seconds to about 4.5 seconds, and the third supply time is about 0.5 seconds to about 4.5 seconds.

10. The method of claim 1, wherein the second supply time and the third supply time are longer than the first supply time.

11. The method of claim 1, wherein the first supply time corresponds to a pseudo-saturation period of the metal precursor.

12. A method of manufacturing a semiconductor device, the method comprising:
forming a plurality of bit lines on a substrate;
forming, on the plurality of bit lines, a mold layer including a plurality of mold openings exposing upper surfaces of the plurality of bit lines;
forming a channel layer covering sidewalls and bottoms of the plurality of mold openings of the mold layer respectively within the plurality of mold openings; and
forming a word line on the channel layer,
wherein the forming of the channel layer includes forming the channel layer by using an atomic layer deposition method including at least one cycle,
wherein the at least one cycle includes:
supplying a metal precursor including one selected from indium (In), gallium (Ga), zinc (Zn), hafnium (Hf), titanium (Ti), aluminum (Al), or zirconium (Zr), onto a substrate to form a first adsorption layer including the metal precursor physically adsorbed onto the substrate;
supplying a first purge gas onto the first adsorption layer;
forming a second adsorption layer by supplying an inert gas in a plasma state onto the first adsorption layer;
supplying a second purge gas onto the second adsorption layer;
supplying a reactant gas as an oxidizing agent in a plasma state onto the second adsorption layer to allow the second adsorption layer to react with the reactant gas to form a metal oxide thin film; and
supplying a third purge gas onto the metal oxide thin film.

13. The method of claim 12, wherein the metal precursor is any one selected from tetrakis(ethylmethylamido)hafnium (TEMAHf), bis(dimethylamino-2-propoxide)diethylindium (DADI), tetrakis(dimethylamido)titanium (TDMATi), dimethylaluminum isopropoxide (DMAI), and tetrakis(ethylmethylamido)zirconium (TEMAZr).

14. The method of claim 12, wherein the reactant gas is oxygen (O₂) or ozone (O₃).

15. The method of claim 12, wherein the metal precursor is supplied for a first supply time, the inert gas is supplied for a second supply time, and the second supply time is longer than the first supply time.

16. The method of claim 15, wherein the first purge gas is supplied for a first purge time, the second purge gas is supplied for a second purge time, the first purge time is longer than the first supply time, and the second purge time is longer than the second supply time.

17. The method of claim 12, wherein the inert gas is helium.

18. The method of claim 12, wherein, in the at least one cycle, a temperature of the substrate is maintained within about 100° C. to about 200° C.

19. A method of manufacturing a thin film by using an atomic layer deposition method including at least one cycle,
wherein the at least one cycle includes:
supplying a metal precursor onto a substrate for a first supply time to form a first adsorption layer including the metal precursor physically adsorbed onto the substrate;
supplying a first purge gas onto the first adsorption layer for a first purge time;
forming a second adsorption layer by supplying an inert gas in a plasma state onto the first adsorption layer for a second supply time;
supplying a second purge gas onto the second adsorption layer for a second purge time;
supplying a reactant gas in a plasma state onto the second adsorption layer for a third supply time to allow the second adsorption layer to react with the reactant gas to form a thin film; and
supplying a third purge gas onto the thin film for a third purge time,
wherein the second supply time is longer than the first supply time, the first purge time is longer than the first supply time, the second purge time is longer than the second supply time, and the inert gas is helium or a mixed gas of helium and argon.

20. The method of claim 19, wherein the metal precursor is at least one selected from tetrakis(ethylmethylamido)hafnium (TEMAHf), bis(dimethylamino-2-propoxide)diethylindium (DADI), tetrakis(dimethylamido)titanium (TDMATi), dimethylaluminum isopropoxide (DMAI), tetrakis(ethylmethylamido)zirconium (TEMAZr), [tris(2,2,6,6-tetramethyl-3,5-heptanedionate) indium, In(thd)₃], [tris(tetramethylheptanedionate) indium, In(tmhd)₃], or [tris(di-isopropylamidinato) indium [tris(di-isopropylamidinato) indium, In(iPr₂-amidinato)₃], [tris(2,2,6,6-tetramethyl-3,5-heptanedionate) gallium, Ga(thd)₃], [tris(tetramethylheptanedionate) gallium, Ga(tmhd)₃], [tris(di-isopropylamidinato) gallium, Ga(iPr₂-amidinato)₃], [bis(2,2,6,6-tetramethyl-3,5-heptanedionate) zinc, Zn(tmhd)₂], [bis(tetram ethylheptanedionate) zinc, Zn(thd)₂], and [bis(di-isopropylguanidinate) zinc, Zn(iPr₂-guanidinate)₂.
